(19) United States
(12) Patent Application Publication
(10) Pub. No.: US 2015/0200186 A1
(43) Pub. Date: Jul. 16, 2015

(54) ELECTRONIC DEVICE, SEMICONDUCTOR PACKAGE, AND METHOD OF MANUFACTURING THE SAME

(71) Applicant: Jin-woo Park, Seoul (KR)

(72) Inventor: Jin-woo Park, Seoul (KR)

(21) Appl. No.: 14/568,113

(22) Filed: Dec. 12, 2014

(30) Foreign Application Priority Data
Jan. 15, 2014 (KR) 10-2014-0005205

(51) Int. Cl. H01L 25/065; H01L 23/00; H01L 23/31; H01L 23/48

(52) U.S. Cl. CPC H01L 25/0657; H01L 23/481; H01L 23/562; H01L 23/3107; H01L 2225/0651; H01L 2225/06513; H01L 2225/06548

(57) ABSTRACT

A semiconductor package includes a substrate; a first semiconductor chip disposed on a first surface of the substrate, the first semiconductor chip either the only semiconductor chip disposed on the first surface of the substrate or a bottom-most semiconductor chip formed on the first surface of the substrate; a plurality of external connection terminals disposed on a second surface of the substrate that is opposite to the first surface of the substrate; a stress buffer layer formed on the first surface of the substrate to vertically overlap at least one of the plurality of external connection members, wherein the stress buffer layer is formed on an edge part of the substrate and does not contact or vertically overlap the first semiconductor chip; and a sealing member covering the first chip and the stress buffer layer.

### CROSS-REFERENCE TO RELATED APPLICATIONS

This application claims the benefit of priority to Korean Patent Application No. 10-2014-0005205, filed on Jan. 15, 2014, in the Korean Intellectual Property Office, the disclosure of which is incorporated herein in its entirety by reference.

### BACKGROUND

The disclosed embodiments relate to a semiconductor package, and more particularly, to a semiconductor package capable of alleviating stress of a substrate on which semiconductor chips are mounted and a method of manufacturing the same.

In general, a plurality of semiconductor chips are formed by performing several semiconductor processes on a wafer. Thereafter, a semiconductor package is formed by performing a packaging process on the wafer to mount each of the plurality of semiconductor chips on a printed circuit board (PCB). The semiconductor package may include a semiconductor chip, a PCB on which the semiconductor chip is mounted, a bonding wire or bump for electrically connecting the semiconductor chip and the PCB, and a sealing member for sealing the semiconductor chip. A memory module may be formed by mounting a plurality of semiconductor packages on a module substrate through solder balls disposed below the PCB. Through the process of forming a semiconductor package or memory module wherein one or more chips is mounted on a substrate and/or PCB, for example, during repeated heating and cooling of certain elements of the package or module, certain connections may separate, become weak, crack, etc. As a result, prevention of such deficiencies may be desirable.

### SUMMARY

The disclosed embodiments provide an electronic device such as semiconductor package having high reliability and good performance, for example, by alleviating stress to be applied to a substrate on which semiconductor chips are mounted due to a difference in a coefficient of thermal expansion (CTE) between the substrate and a sealing member and/or the semiconductor chips, and a method of manufacturing the same.

According to one embodiment, a semiconductor package includes: a substrate; a first semiconductor chip disposed on a first surface of the substrate, the first semiconductor chip either the only semiconductor chip disposed on the first surface of the substrate or a bottom-most semiconductor chip formed on the first surface of the substrate; a plurality of external connection terminals disposed on a second surface of the substrate that is opposite to the first surface of the substrate; a stress buffer layer formed on the first surface of the substrate to vertically overlap at least one of the plurality of external connection members, wherein the stress buffer layer is formed on an edge part of the substrate and does not contact or vertically overlap the first semiconductor chip; and a sealing member covering the first chip and the stress buffer layer.

The stress buffer layer may have a modulus that reduces stress and/or strain resulting from a difference in a coefficient of thermal expansion (CTE) between the substrate and the sealing member.

In one embodiment, the stress buffer layer has a modulus that is lower than that of the substrate.

In one embodiment, the stress buffer layer has a modulus that is lower than that of each of the substrate, the first semiconductor chip, and the sealing member.

In one embodiment, the stress buffer layer is formed at a portion on the first surface of the substrate outside of a portion where the first semiconductor chip is disposed.

In certain embodiments, the stress buffer layer includes at least two buffer structures at opposite ends of the substrate, each buffer structure extending lengthwise along an edge part of the substrate and extending width-wise from inside an edge of the substrate to the edge of the substrate.

The stress buffer layer may be formed on the first surface of the substrate in a symmetrical form based on the first semiconductor chip.

In one embodiment, the stress buffer layer is formed on the first surface of the substrate and at two facing sides or four sides of the first semiconductor chip.

In one embodiment, the stress buffer layer is exposed from a side surface of the sealing member.

In certain embodiments, a second semiconductor chip may be stacked on the first semiconductor chip. The first semiconductor chip may be disposed on the substrate and an inactive surface thereof faces the first surface of the substrate, and the first semiconductor chip may be electrically connected to the substrate through a plurality of wires. In exemplary embodiments, the second semiconductor chip is stacked on the first semiconductor chip through a bump and an active surface thereof faces an active surface of the first semiconductor chip, and the second semiconductor chip electrically connects to the substrate through the bump, a rewiring of the first semiconductor chip, and the wire.

In certain embodiments, the first semiconductor chip is part of a stack of semiconductor chips including at least a second semiconductor chip stacked on the first semiconductor chip, and a semiconductor chip of the stack of semiconductor chips closest to the substrate is connected to the substrate through a plurality of bumps, and remaining semiconductor chips of the stack of semiconductor chips are electrically connected to the substrate through a plurality of through substrate vias.

According to other exemplary embodiments, an electronic device includes: a package substrate; a first semiconductor chip disposed on a first surface of the package substrate, the first semiconductor chip either the only semiconductor chip disposed on the first surface of the package substrate or a bottom-most semiconductor chip formed on the first surface of the package substrate; a plurality of external connection terminals disposed on a second surface of the package substrate that is opposite to the first surface of the package substrate; a capping layer covering the first semiconductor chip and covering the first surface of the substrate; a first buffer structure formed between the first surface of the substrate and the capping layer at a first edge portion of the substrate, the first buffer structure separated from a first side of the first semiconductor chip by a predetermined distance; and a second buffer structure formed between the first surface of the substrate and the capping member at a second edge portion of the substrate, the second edge portion opposite the first edge portion, and the second buffer structure separated from a second side of the first semiconductor chip by a predetermined distance. Each of the first and second buffer structures may have a modulus that is less than the modulus of the package substrate and less than the modulus of the capping layer.

In certain embodiments, each of the first and second buffer structures covers a respective set of external connection terminals of the plurality of connection terminals.

In one embodiment, the first and second buffer structures are part of a stress buffer layer, and the stress buffer layer has a modulus that reduces a stress or strain influence from the capping layer when the package substrate contracts or expands.

In one embodiment, the modulus of each of the first and second buffer structures is less than 5% of the modulus of each of the package substrate and the capping layer.

The electronic device may additionally include a module substrate on which the package substrate is mounted.

According to yet another embodiment, a semiconductor device includes: a substrate; a plurality of external connection terminals on a bottom surface of the substrate; a stack of semiconductor chips disposed on a top surface of the substrate, the stack of semiconductor chips including a lower-most semiconductor chip, and one or more additional semiconductor chips; a capping layer disposed on the top surface of the substrate; and an edge interface layer formed at an interface between the capping layer and the top surface of the substrate, at a location outside of outer boundaries of the lower-most semiconductor chip and separated from the lower-most semiconductor chip. The edge interface layer may be formed of a material that reduces a stress or strain influence from the capping layer on the substrate when the substrate contracts or expands.

In one embodiment, the edge interface layer has a modulus that is lower than that of each of the substrate, the semiconductor chips, and the capping layer, and the edge interface layer is formed at an edge portion on the first surface of the substrate and covers at least a plurality of outer-most external connection terminals of the plurality of external connection terminals.

The substrate may be a package substrate, and the edge interface layer may extend to at least one edge of the package substrate, such that side surfaces of the package substrate and the edge interface layer are substantially coplanar.

In one embodiment, the edge interface layer is formed at two opposite sides of the substrate, or at four sides of the substrate.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view of a semiconductor package according to an embodiment of the inventive concept;

FIGS. 2A to 2E are top views of semiconductor packages according to embodiments of the inventive concept;

FIG. 3 is a cross-sectional view of a semiconductor package according to another embodiment of the inventive concept;

FIG. 4 is a cross-sectional view of a semiconductor package according to another embodiment of the inventive concept;

FIGS. 5A and 5B are a cross-sectional view and a top view of a semiconductor package according to embodiments of the inventive concept;

FIG. 6 is a circuit diagram showing an electrical connection relationship of first and second semiconductor chips in the semiconductor package of FIG. 1, according to one embodiment of the inventive concept;

FIGS. 7A and 7B are top views showing an electrical connection relationship of pads and bumps in the first and second semiconductor chips on the basis of the circuit diagram of FIG. 6, according to one embodiment of the inventive concept;

FIG. 8 is a cross-sectional view of a semiconductor package according to another embodiment of the inventive concept;

FIG. 9 is a cross-sectional view of a semiconductor package according to another embodiment of the inventive concept;

FIG. 10 is a cross-sectional view of a semiconductor package according to another embodiment of the inventive concept;

FIGS. 11A and 11B are a cross-sectional view and a top view of a semiconductor package according to another embodiment of the inventive concept;

FIG. 12 is a cross-sectional view of a semiconductor package according to another embodiment of the inventive concept;

FIG. 13 is a cross-sectional view of a semiconductor package according to another embodiment of the inventive concept;

FIG. 14 is a cross-sectional view of a semiconductor package according to another embodiment of the inventive concept;

FIG. 15 is a cross-sectional view of a semiconductor package according to another embodiment of the inventive concept;

FIG. 16 is a cross-sectional view of a semiconductor package according to another embodiment of the inventive concept;

FIGS. 17A and 17B are a cross-sectional view and a top view of a semiconductor package according to another embodiment of the inventive concept;

FIGS. 18A and 18B are a top view and a bottom view of a memory module, and FIG. 18C is a cross-sectional view along line III-III′ of FIG. 18A;

FIGS. 19A to 19F are cross-sectional views for describing a method of manufacturing a semiconductor package, according to an embodiment of the inventive concept;

FIG. 20 is a block diagram of a memory card including a semiconductor package according to one or more embodiments of the inventive concept;

FIG. 21 is a block diagram of an exemplary electronic system including a semiconductor package according to one or more embodiments of the inventive concept; and

FIG. 22 is a perspective view of an exemplary electronic device to which a semiconductor package according to one or more embodiments of the inventive concept is applied.

### DETAILED DESCRIPTION OF THE EMBODIMENTS

Exemplary embodiments of the inventive concept will now be described in detail with reference to the accompanying drawings.

The embodiments are provided to describe the inventive concept more fully to those of ordinary skill in the art. The embodiments may, however, be embodied in many different forms and should not be construed as being limited to the embodiments set forth herein.

In the description below, when it is described that a certain component is connected to another component, the certain component may be directly connected to another component, or a third component may be interposed therebetween. Similarly, when it is described that a certain component is above another component, the certain component may be directly above another component, or a third component may be interposed therebetween. Other terms, such as “between,” “on,” or “adjacent to,” conform to the same interpretation. However, if two components are described as “contacting” each other, or as being “directly connected to,” “directly above,” each other, etc., unless the context clearly indicates otherwise, these terms indicate that no intervening components are present.

It will be understood that, although the terms first, second, etc. may be used herein to describe various elements, these elements should not be limited by these terms. Unless indicated otherwise, these terms are only used to distinguish one element from another. For example, a first chip could be termed a second chip, and, similarly, a second chip could be termed a first chip without departing from the teachings of the disclosure.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures have schematic properties, and shapes of regions shown in figures exemplify specific shapes of regions of elements, and the specific properties and shapes do not limit aspects of the invention.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning.

In the drawings, the structures or sizes of components are exaggerated for convenience and clarity of description, and parts irrelevant to the description are omitted. Like reference numerals in the drawings denote like elements.

All terms used herein including technical or scientific terms have the same meaning as those generally understood by those of ordinary skill in the art unless they are defined differently. It should be understood that terms generally used, which are defined in a dictionary, have the same meaning as in context of related technology, and the terms are not understood as ideal or excessively formal meaning unless they are clearly defined in the application. The terminology used in the application is used only to describe specific embodiments and does not have any intention to limit the inventive concept.

As used herein, the term “and/or” includes any and all combinations of one or more of the associated listed items. As used herein, the singular forms “a”, “an” and “the” are intended to include the plural forms as well, unless the context clearly indicates otherwise. Expressions such as “at least one of,” when preceding a list of elements, modify the entire list of elements and do not modify the individual elements of the list.

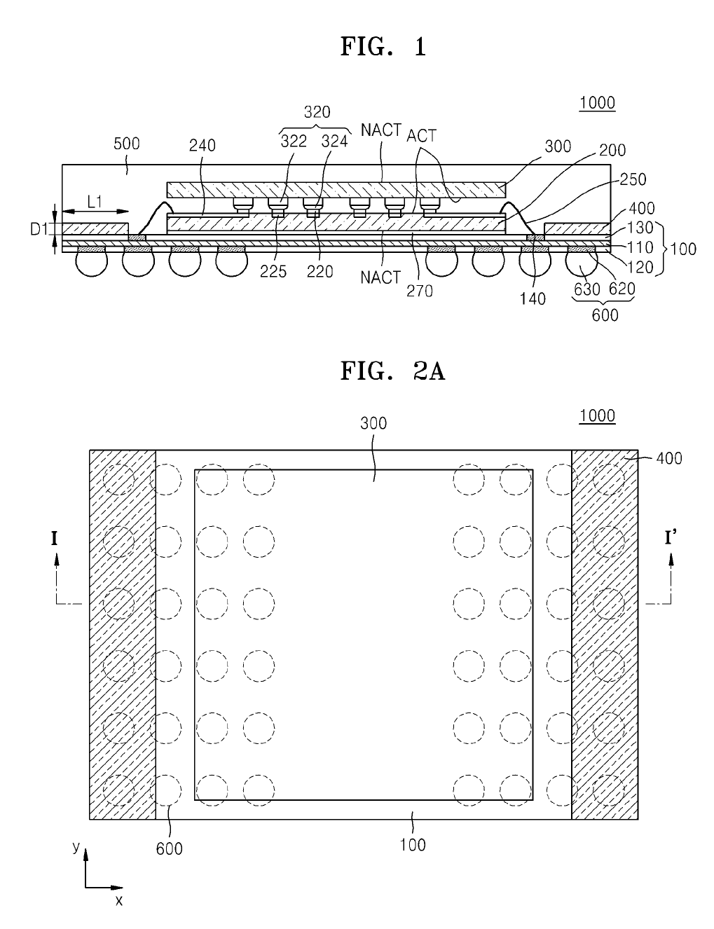

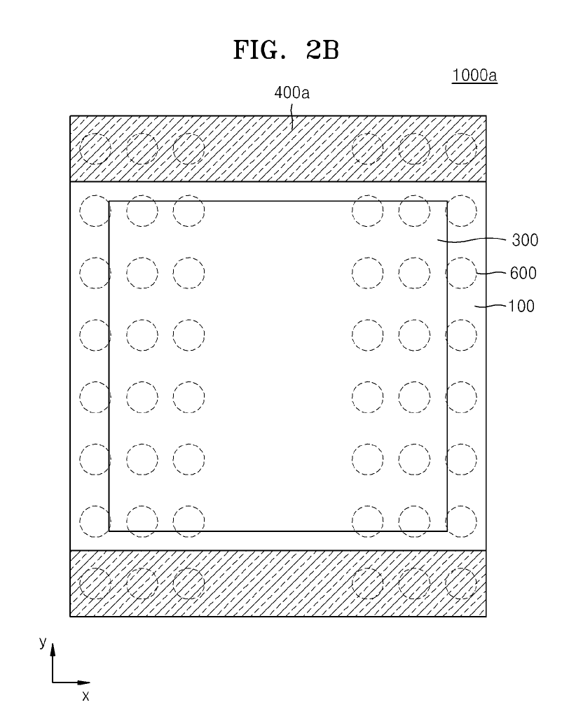

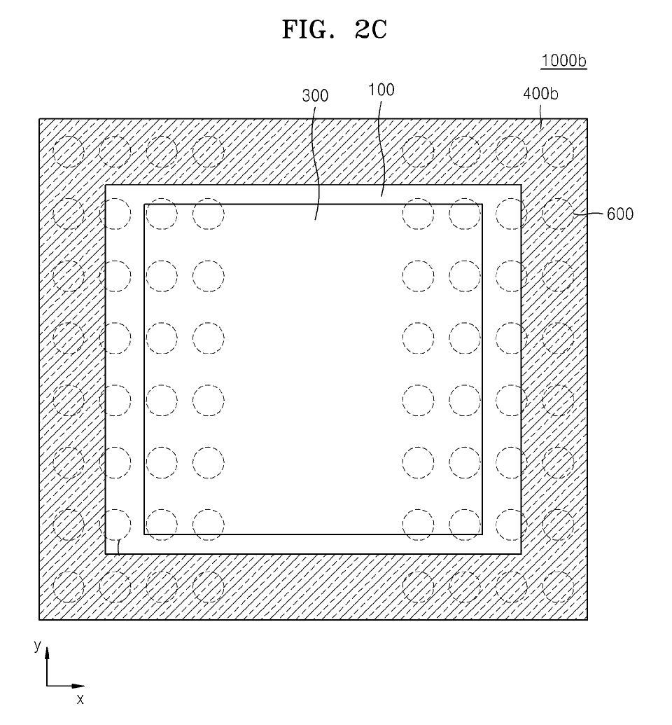

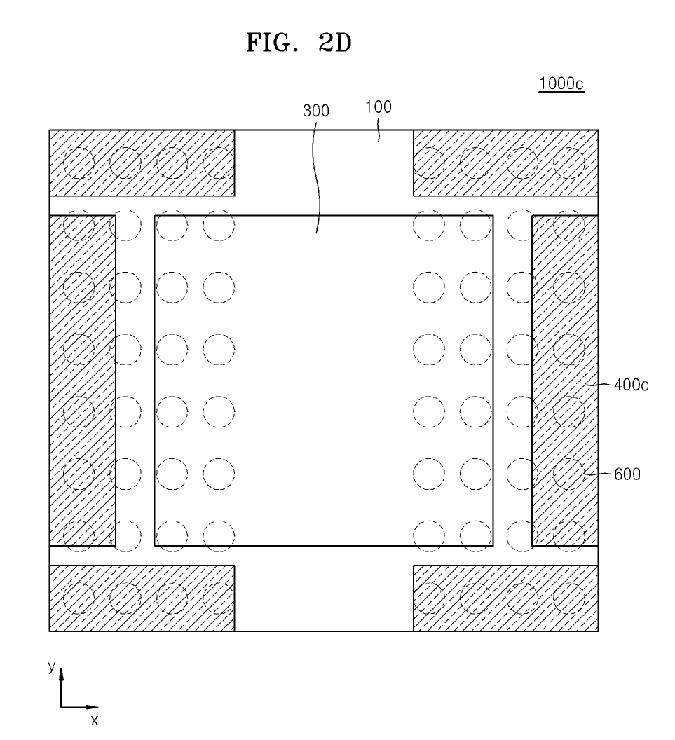

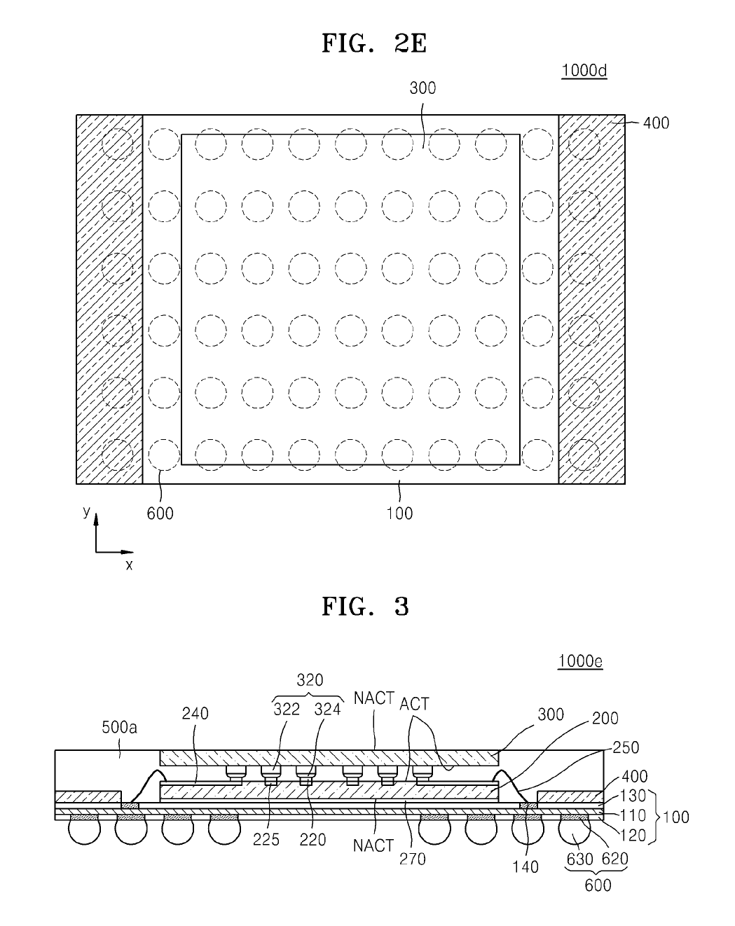

FIG. 1 is a cross-sectional view of a semiconductor package 1000 according to an embodiment of the inventive concept and may correspond to a part cut along line I-I′ of FIG. 2A.

Referring to FIG. 1, the semiconductor package 1000 according to an embodiment of the inventive concept may include a substrate 100, a first semiconductor chip 200, a second semiconductor chip 300, a stress buffer layer 400, a sealing member 500 (also referred to herein as a capping layer, or molding layer), and an external connection member 600.

The substrate 100 is a support substrate on an upper part of which the first semiconductor chip 200 and the second semiconductor chip 300 are mounted, and may include a body layer 110, a lower protective layer 120, and an upper protective layer 130. The substrate 100 may be formed on the basis of a printed circuit board (PCB), a ceramic substrate, a glass substrate, an interposer substrate, or the like. According to circumstances, the substrate 100 may be formed from an active wafer. The active wafer is a wafer, such as a silicon wafer on which a semiconductor chip is formed.

In the semiconductor package 1000 according to the current embodiment, the substrate 100 may be a PCB, e.g., a molded underfill (MUF) PCB. Of course, the substrate 100 is not limited to the MUF PCB. Herein, an MUF process is a process of sealing an edge part of a semiconductor chip and a space part between the semiconductor chip and a PCB or between semiconductor chips through a one-shot molding process. The PCB used in the MUF process is called an MUF PCB. Wirings (not shown) are formed on the substrate 100 and may be electrically connected to circuitry (e.g., an integrated circuit) of the first and second semiconductor chips 200 and 300 through wire bonding or flip-chip bonding. Alternatively, through substrate vias may be used to electrically connect circuitry of the first and second semiconductor chips 200 and 300 to the substrate 100. In addition, the external connection member 600 may be disposed on a surface of the substrate 100 that is opposite to the other surface on which the first and second semiconductor chips 200 and 300 are mounted. The substrate 100 may be mounted on a module substrate or a system board through the external connection member 600. Note that although exemplary external connection member 600 is described herein, as shown in the figures, a plurality of external connection members 600 will typically be used.

A multi-layer or single-layer wiring pattern (not shown) may be formed inside the body layer, and the external connection member 600 and a substrate pad 140 may be electrically connected to each other through the wiring pattern. The lower protective layer 120 and the upper protective layer 130 functions to protect the body layer 110 and may be formed of, for example, a solder resist (SR). Also, the different conductive connectors, such as substrate pad 140, external connection member 600, etc., may be referred to herein terminals, or conductive terminals (e.g., substrate terminal 140, external connection terminal 600, etc.).

When the substrate 100 is a PCB, the body layer 110 may be implemented for example by compressing a phenol or epoxy (or FR-4) resin or the like to a predetermined thin thickness, depositing a conductive film, such as a copper foil on both surfaces of the compressed resin, and forming wiring patterns, which are transfer paths of an electrical signal, through patterning on the copper foils. In addition, the wiring patterns formed on the upper and lower surfaces of the body layer 110 may be electrically connected to each other through via contacts (not shown) permeating the body layer 110, and the lower and upper protective layers 120 and 130 may be implemented by coating a solder resist layer on the whole upper and lower surfaces of the body layer 110 except for terminal connection portions, e.g., the substrate pad 140 and an external lower pad 620.

The PCB may be classified into a single-layer PCB having a wiring on only one surface thereof and a double-layer PCB having wirings on both surfaces thereof. The copper foil may be formed in three or more layers by using an insulator named prepreg, and a multi-layer-wiring PCB may be implemented by forming three or more wiring layers according to the number of formed layers of the copper foil. Of course, in the semiconductor package 1000 according to the current embodiment, the substrate 100 is not limited to the structures or materials described above.

In one embodiment, the first semiconductor chip 200 may include an active surface ACT and an inactive surface NACT, and the first semiconductor chip 200 may be stacked on the substrate 100 by adhering and fixing the inactive surface NACT to the substrate 100 through an adhesive member 270. The adhesive member 270 may include, for example, a layer formed of a non-conductive film (NCF), an anisotropic conductive film (ACF), a ultraviolet (UV) film, an instantaneous adhesive, a thermosetting adhesive, a laser hardening adhesive, an ultrasonic hardening adhesive, a non-conductive paste (NCP), or the like. In one embodiment, the adhesive member 270 may be a die attach film (DAF). Of course, the adhesive member 270 is not limited to the materials and structures described above.

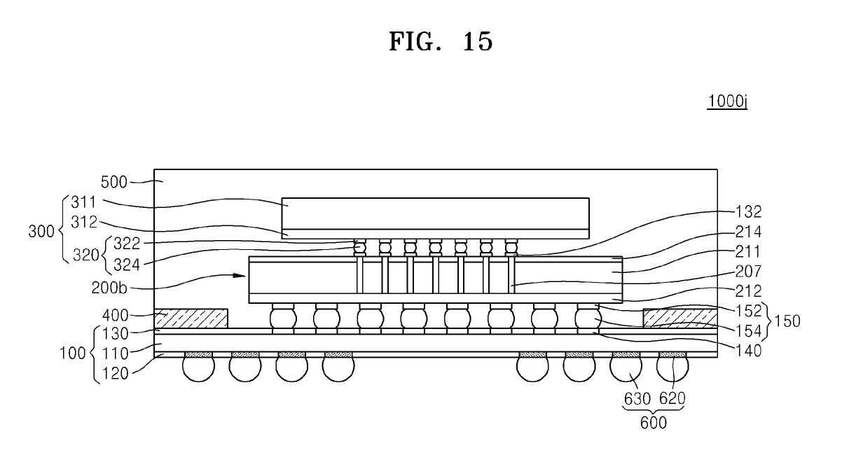

The first semiconductor chip 200 may include a body part (not shown, refer to 211 of FIG. 15), a wiring part (not shown, refer to 212 of FIG. 15), a protective layer (not shown), and the like. The first semiconductor chip 200 may formed on the basis of an active wafer.

When the first semiconductor chip 200 is formed on the basis of an active wafer, the body part may include a semiconductor substrate (not shown), an integrated circuit layer (not shown), an inter-layer insulating layer (not shown), and the like. The wiring part disposed on the body part may include an inter-metal insulating layer (not shown) and a multi-layer wiring layer (not shown) in the inter-metal insulating layer.

A semiconductor substrate that is used for the body part may include a IV-group material wafer, such as for example a silicon wafer, or a III-V-group compound wafer. The semiconductor substrate may be formed from a monocrystalline wafer, such as a silicon monocrystalline wafer, in view of a forming method. However, the semiconductor substrate is not limited to the monocrystalline wafer, and various wafers, such as an epitaxial wafer, a polished wafer, an annealed wafer, a silicon on insulator (SOI) wafer, and the like, may be used for the semiconductor substrate. The epitaxial wafer is a wafer obtained by growing a crystalline material on a monocrystalline silicon substrate.

Although not shown in FIG. 1, a protective layer may be formed on the wiring part of the active surface ACT. The protective layer may function to protect the first semiconductor chip 200 from external physical and chemical damages. The protective layer may be formed as an oxide layer, a nitride layer, or a double layer thereof. In detail, the protective layer may be formed as an oxide layer, e.g., a silicon oxide (SiO₂) layer, a nitride layer, e.g., a silicon nitride (SiNₓ) layer, or a combination thereof.

A plurality of terminals, such as bump pads 225, and rewirings 240 (also described as redistribution lines or redistribution terminals) may be formed on the active surface ACT of the first semiconductor chip 200. A first bump 220 may be disposed on each of the plurality of bump pads 225. The first bump 220 may include, for example, only a copper (Cu) pillar or the Cu pillar and solder. Each first bump 220 and/or its corresponding bump pad 225 may be individually or collectively referred to as a terminal, such as an interconnection terminal, or inter-chip terminal. The first bump 220 is physically and electrically coupled to a second bump 320 of the second semiconductor chip 300 (which may also be referred to generally as an interconnection terminal, or as an inter-chip terminal).

The plurality of bump pads 225 may be electrically connected through the plurality of rewirings 240 to bonding pads (not shown) disposed at edge parts of the first semiconductor chip 200. Each of the bonding pads may be electrically connected to the substrate pad 140 through a wire 250. The wire 250 may be formed of a metal, such as Cu, aluminum (Al), gold (Au), an Au alloy, or the like.

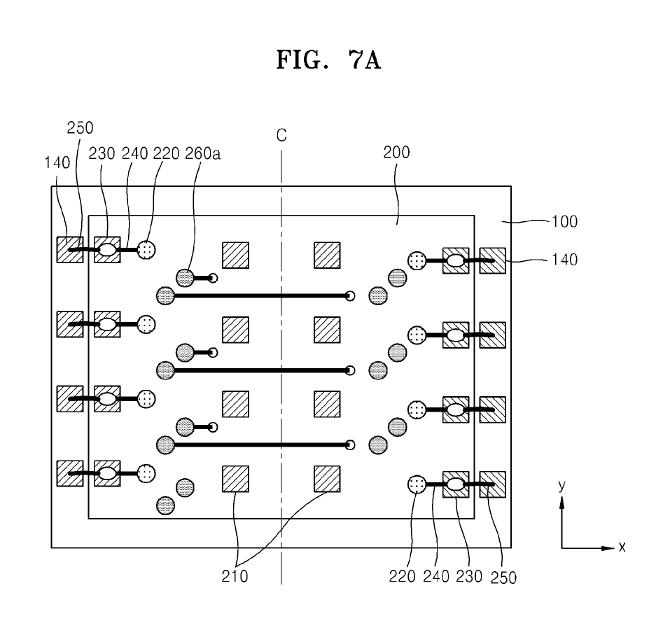

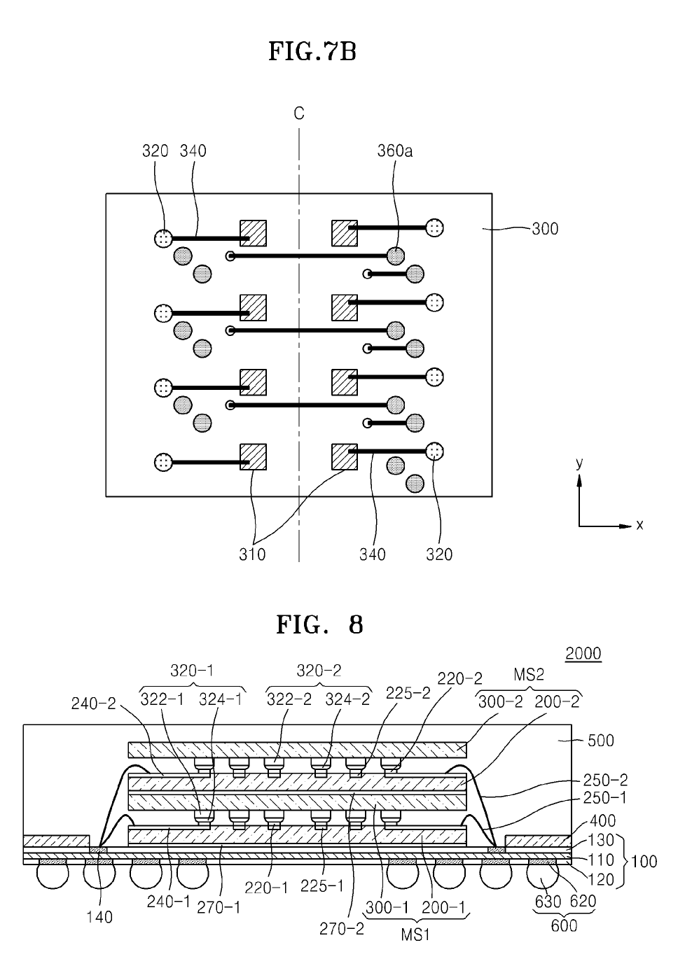

Although FIG. 1 shows that only the plurality of bump pads 225 are disposed on the first semiconductor chip 200 and are all connected to second bumps 320 of the second semiconductor chip 300, the illustration of FIG. 1 is for conciseness of the drawing or convenience of understanding according to a cut portion, and various kinds of pads may be actually disposed on the active surface ACT of the first semiconductor chip 200. The arrangement of the various kinds of pads will be described in more detail with reference to FIGS. 7A and 7B.

The first semiconductor chip 200 may include a memory device or a non-memory device. The memory device may include, for example, dynamic random access memory (DRAM), static RAM (SRAM), flash memory, electrically erasable programmable read-only memory (EEPROM), programmable RAM (PRAM), magnetoresistive RAM (MRAM), and resistive RAM (RRAM). The non-memory device may be a logic device, such as a microprocessor, a digital signal processor, or a microcontroller, or a similar device. In one embodiment, the first semiconductor chip 200 may be a memory device, such as DRAM. The first semiconductor chip may also include both a memory device and a logic device, for example disposed in different regions of the first semiconductor chip.

Like the first semiconductor chip 200, the second semiconductor chip 300 may include an active surface ACT and an inactive surface NACT. The second semiconductor chip 300 may be stacked on the first semiconductor chip 200 through the second bumps 320, for example, by a flip-chip method. In one embodiment, a structure of the second semiconductor chip 300 is the same as described with respect to the first semiconductor chip 200. For example, the second semiconductor chip 300 may be formed on the basis of an active wafer and may include a body part (not shown), a wiring part (not shown), a protective layer (not shown), and the like. The body part may include a semiconductor substrate (not shown), an integrated circuit layer (not shown), an inter-layer insulating layer (not shown), and the like, and the wiring part may include an inter-metal insulating layer (not shown) and a multi-layer wiring layer (not shown). The protective layer may be formed on the wiring part of the active surface ACT of the second semiconductor chip 300.

A plurality of pads (not shown) may be formed on the active surface ACT of the second semiconductor chip 300, and the second bump 320 may be disposed on each of the plurality of pads. The second bump 320 may include, for example, a Cu pillar 322 and a solder 324. Each second bump 320 and/or its corresponding bump pad may be individually or collectively referred to as a terminal, such as an interconnection terminal, or inter-chip terminal. When the first bump 220 includes solder, the second bump 320 may include only the Cu pillar 322. According to circumstances, each of the first bump 220 and the second bump 320 may include solder. Of course, materials of the first bump 220 and the second bump 320 are not limited the materials described above. An exemplary location relationship between pads formed on the second semiconductor chip 300 and the second bumps 320 will be described in more detail with reference to FIG. 7B.

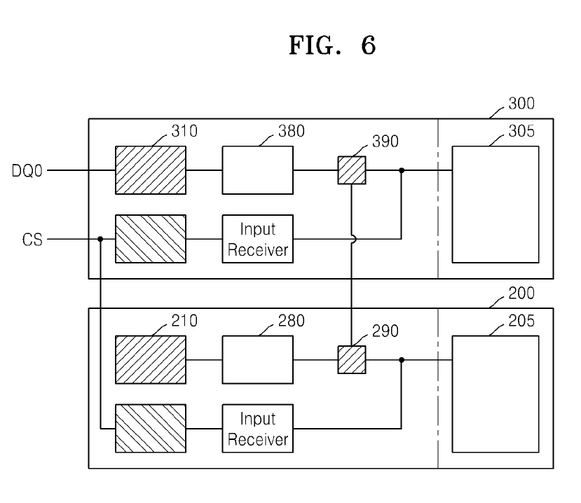

In the structure of the semiconductor package 1000 according to the current embodiment, the first semiconductor chip 200 and the second semiconductor chip 300 may be stacked in a mirror shape so as to face each other by a flip-chip bonding method, thereby forming a mirror-type stacking structure at least with respect to external terminals on the two chips. The mirror-type stacking structure will be described in more detail with reference to FIGS. 7A and 7B. In the semiconductor package structure according to the current embodiment, any one of the first semiconductor chip 200 and the second semiconductor chip 300 may be a master chip, and the other one may be a slave chip. The master chip may be a semiconductor chip in which an input/output pad is connected to the substrate pad 140 to directly input/output data, and the slave chip may be a semiconductor chip in which an input/output pad is not connected to the substrate pad 140, and thus data of which is input/output passes through the master chip. A circuit connection relationship between the master chip and the slave chip will be described in more detail with reference to FIG. 6.

The stress buffer layer 400 may be disposed at an edge part of the substrate 100 and may have a relatively low modulus compared with the other components. The modulus may indicate a Young's modulus. As a reference, the modulus indicates a modulus of elasticity, wherein a material having a low modulus may be flexible or gentle, and a material having a high modulus may be rigid or stiff.

The stress buffer layer 400 may be formed of a material capable of buffering stress applied to the substrate 100 due to a difference in a coefficient of thermal expansion (CTE) between the substrate 100 and the sealing member 500. For example, the stress buffer layer 400 may be formed of a material capable of increasing a CTE of the substrate 100 with a low modulus.

In more detail, in general, a modulus of a semiconductor chip may be about 7 GPa at a normal temperature, a modulus of an epoxy molding compound (EMC) that may be used to form the sealing member 500 may be about 15 GPa to about 30 GPa, a modulus of a PCB, specifically, a PCB core corresponding to a body, may be about 10 GPa to about 30 GPa, and a modulus of a die attach film (DAF) may be about 300 MPa to about 1000 MPa. Based on a CTE, a CTE of a semiconductor chip may be about 3 ppm to about 4 ppm, a CTE of an EMC may be about 3 ppm to about 30 ppm, a CTE of a PCB core may be about 3 ppm to about 20 ppm, and a CTE of a DAF may be about 50 ppm to about 150 ppm. In certain embodiments, the modulus of buffer structures of a stress buffer layer may be at least an order of magnitude smaller than the modulus of each of the package substrate and a capping layer (e.g., less than 5%), and in some cases 2 to 3 magnitudes smaller. The higher the temperature, the lower a modulus and a CTE.

As described above, since modulus and CTE values of components of the semiconductor package 1000 are different from each other, when the components are expanded and/or contracted according to a change in an ambient temperature, stress may be applied to each other. For example, due to a CTE difference between the substrate 100 and an EMC frequently used for the sealing member 500, much stress may be applied to the substrate 100, and accordingly, a failure may frequently occur such that an edge part of the substrate 100 is bent.

An EMC may have a different modulus or CTE according to constituent materials or the contained quantity of a filler, and in general, an EMC for sealing an edge of a semiconductor chip tends to have a higher modulus and a lower CTE than the substrate 100. Accordingly, in expansion due to an increase in a temperature, the substrate 100 is more expanded than the EMC. However, as shown in FIG. 1, since the substrate 100 and the EMC adhere and are fixed to each other at an edge part of the semiconductor package 1000, the EMC acts as stress for restraining the expansion of the substrate 100. Due to the stress applied to the substrate 100, the substrate 100 may be bent upwards (e.g., edges may become higher than the middle portion), and the bending of the substrate 100 may cause a bad contact, a crack, a separation, or the like of the external connection member 600, e.g., a solder ball, disposed below the substrate 100.

Specifically, the failure of the external connection member 600 may frequently occur at an edge part of the substrate 100 because the expansion of the substrate 100 due to thermal expansion gradually increases towards the edge part according to general physical characteristics, and the substrate 100 is directly coupled and fixed to the EMC at the edge part, thereby generating the highest stress at the edge part. Stress due to a CTE difference between the first semiconductor chip 200 and the substrate 100 at a central part of the substrate 100 may also be applied to substrate 100. However, as described above, an increase in expansion due to thermal expansion at the central part is relatively small, and in certain examples, the first semiconductor chip 200 adheres and is fixed to the substrate 100 by using an adhesive member having a relatively low modulus and a relatively high CTE, e.g., a DAF, and thus, the DAF may buffer the stress applied from the first semiconductor chip 200 to the substrate 100. Accordingly, the stress received from the first semiconductor chip 200 at the central part of the substrate 100 may be small.

Although a case where the CTE of the EMC is lower than that of the substrate 100 has been described, an opposite case is not excluded. For example, the CTE of the EMC may be higher than that of the substrate 100 according to materials of the EMC, and in this case, the expansion of the EMC may be restrained by the substrate 100, and accordingly, the substrate 100 may be bent downwards. Even when the substrate 100 is bent downwards, a failure of the external connection member 600 may occur.

Furthermore, when it is considered that the semiconductor package 1000 is mounted on a board, such as a module substrate of a memory module, through the external connection member 600, the occurrence of the abnormalities in the substrate 100 and the external connection member 600 may cause a thermal cycle (TC) reliability in board level reliability (BLR) to be very weak. The TC reliability is a result of testing whether the reliability is maintained up to a predetermined number of cycles by periodically increasing and decreasing a temperature at a board level. For example, the TC reliability may be obtained by testing whether the performance is still maintained when the TC reliability test is repeated more than 1000 cycles at a board level, wherein one cycle indicates a change in a temperature between about 0° C. and about 125° C. during about 30 minutes to about 45 minutes.

As described above, in a semiconductor device including a capping layer covering a first semiconductor chip and covering a first surface of the substrate, a first buffer structure may be formed between the first surface of the substrate and the capping layer at a first edge portion of the substrate. As shown in FIG. 1, the first buffer structure may be separated or spaced apart from a first side of the first semiconductor chip by a predetermined distance. Similarly, at least a second buffer structure may be formed between the first surface of the substrate and the capping member at a second edge portion of the substrate opposite the first edge portion. The second buffer structure may be separated or spaced apart from a second side of the first semiconductor chip by a predetermined distance. The first buffer structure and second buffer structure may be described as part of the same stress buffer layer. The separation distances may be the same for each side of the semiconductor chip, but need not be the same.

In the semiconductor package 1000 according to certain embodiments, the stress buffer layer 400 may have a low modulus of, for example, about 0.1 MPa to about 500 MPa and have a high CTE of, for example, about 100 ppm to about 1000 ppm. Due to the low modulus and/or the high CTE of the stress buffer layer 400, the stress buffer layer 400 may buffer the stress to be applied to the substrate 100. For example, due to the stress buffer layer 400 disposed between the sealing member 500 and the substrate 100, the substrate 100 may be expanded and/or contracted with little influence of the sealing member 500.

As a reference, a low modulus indicates high flexibility like an elastic cord, and a high CTE indicates an increase in expansion and contraction. Therefore, when the stress buffer layer 400 is disposed between the sealing member 500 and the substrate 100, the substrate 100 may be free to be expanded and contracted with the stress buffer layer 400 and may not be influenced from the sealing member 500 at a portion where the stress buffer layer 400 is disposed. As a result, the stress buffer layer 400 may function to decrease a modulus of the substrate 100 and to increase a CTE of the substrate 100. The sealing member 500 is also referred to herein as a mold, or a mold structure.

The stress buffer layer 400 may be formed of, for example, silicone, epoxy, polyimide, a mixture of silicone and epoxy, a mixture of polyimide and epoxy, or the like. The epoxy may contain a filler, and a modulus and a CTE of the stress buffer layer 400 may vary according to the contained quantity of the filler. When the stress buffer layer 400 is formed of epoxy, the stress buffer layer 400 may contain a relatively little filler to thereby have a low modulus and a high CTE. The stress buffer layer 400 may be coated and formed in a liquid type on the substrate 100 or may be adhered and formed in a thin film type on the substrate 100.

A thickness D1 of the stress buffer layer 400 may be about 10 μm to about 100 μm. The thicker the thickness D1, the greater the stress buffering function. However, by considering that the stress buffer layer 400 cannot fully replace the function of the sealing member 500, the stress buffer layer 400 may be formed within a particular range of thickness. For example, in the semiconductor package 1000 according to the current embodiment, the stress buffer layer 400 may be formed with a thickness of about 40 μm. A width of the stress buffer layer 400 may be a first length L1, and the first length L1 may be determined in consideration of a size difference between the first semiconductor chip 200 and the substrate 100, a secured wire bonding area, and the like. In addition, a length of the stress buffer layer 400 in a second direction (a y direction of FIG. 2A) may be the same as a length of the substrate 100 in the second direction. Of course, the length of the stress buffer layer 400 in the second direction (a y direction of FIG. 2A) may be different from the length of the substrate 100 in the second direction. The stress buffer layer 400 may also be referred to herein as an interface layer, for example, an edge interface layer, or as a buffer structure.

The sealing member 500 may seal the side surfaces and the upper surfaces of the first semiconductor chip 200 and the second semiconductor chip 300. However, as shown in FIG. 1, one side surface of the stress buffer layer 400 may be exposed through a side surface of the sealing member 500. The sealing member 500 may be formed, for example, of an EMC. For example, in one embodiment, the EMC may have a modulus of about 15 GPa to about 30 GPa and a CTE of about 3 ppm to about 30 ppm as described above. The sealing member 500 is not limited to the EMC and may be formed of various materials, e.g., an epoxy-group material, a thermosetting material, a thermoplastic material, a UV-treated material, and the like. The thermosetting material may include a phenol-, acidic-anhydride-, or ammine-type hardening agent and an additive of acrylpolymer. The sealing member 500 may be formed of epoxy and may contain a relatively large amount of filler. For example, the sealing member 500 may be formed of an epoxy-group material containing a silica filler as about 80%.

The sealing member 500 may be formed by an MUF process, and accordingly, a material covering edges of the first semiconductor chip 200 and the second semiconductor chip 300 may be the same as a material filling between the first semiconductor chip 200 and the second semiconductor chip 300. As shown in FIG. 1, first bumps 220 and the second bumps 320 may be disposed between the first semiconductor chip 200 and the second semiconductor chip 300 and be surrounded by the sealing member 500.

The external connection members 600 may function to mount the entire semiconductor package 1000 on an external system substrate or module substrate. For example, the semiconductor package 1000 according to the current embodiment may be mounted on a module substrate of a memory module through the external connection members 600. Each external connection member 600, also referred to herein as an external connection terminal, may include conductive interconnects, such as the external lower pad 620 and a connection member 630. The external connection member 600 may have a larger size than that of the first bump 220 or the second bump 320 as shown in FIG. 1. The external connection terminals 600 may include inner terminals, and outer-most terminals (e.g., terminals closest to edges of the substrate). As a reference, a wiring formed on a system substrate or a module substrate may be standardized or have a limitation such that it is difficult to be crowded due to a physical characteristic of the module substrate. Accordingly, an interval and a size of the external connection members 600 of the semiconductor package 1000 mounted on the system substrate or the module substrate may be larger than an interval and a size of a connection member between semiconductor chips in the semiconductor package 1000.

The external lower pad 620 may be exposed with respect to the lower protective layer 120 and electrically connected to the wiring pattern in the body layer 110. The external lower pad 620 may be formed, for example, of Al, Cu, or the like and formed by a pulse plating method or a direct current (DC) plating method. However, a material and a forming method of the external lower pad 620 are not limited to the materials and the methods described above.

The connection member 630 may be formed of a conductive material, e.g., Cu, Al, silver (Ag), tin (Sn), Au, solder, or the like. However, a material of the connection member 630 is not limited thereto. The connection member 630 may be formed in multiple layers or in a single layer. For example, when the connection member 630 is formed in multiple layers, the connection member 630 may include a Cu pillar and solder as in the first bump 220 or the second bump 320. When the connection member 630 is formed in a single layer, the connection member 630 may be formed, for example, of Sn—Ag solder or Cu. In the semiconductor package 1000 according to the current embodiment, the connection member 630 may be a solder ball.

The semiconductor package 1000 according to the current embodiment may include the stress buffer layer 400 disposed between the substrate 100 and the sealing member 500 at an edge part of the substrate 100 and having a relatively low modulus and a relatively high CTE. With the presence of the stress buffer layer 400, stress to be applied to the substrate 100 due to a CTE difference between the substrate 100 and the sealing member 500 may be buffered. Therefore, the substrate 100 may be prevented from being bent, and abnormalities, such as a bad contact, a crack, a separation, and the like, of the external connection member 600 disposed below the substrate 100 may be prevented. As a result, when it is considered that the semiconductor package 1000 is mounted on a board, such as a module substrate, through the external connection member 600, the TC reliability in the BLR may be improved.

The stress buffer layer 400 may be disposed at an edge part of the substrate 100 in various forms which will be described below with reference to FIGS. 2A to 2E. In one embodiment, the stress buffer layer 400 may be disposed on the entire substrate 100 instead of only the edge part of the substrate 100. However, it is particularly useful to include the stress buffer layer 400 at the edge part of the substrate 100 to relieve stress in certain situations where it may be a maximum and most likely to cause connection problems for the substrate 100. Further, as shown in various embodiments, stress buffer structures may be formed outside of an area occupied by a semiconductor chip adjacent the substrate. In various embodiments, stress buffer structures do not contact or vertically overlap any part of the semiconductor chip adjacent the substrate. As a result, the stress buffer layer 400 may be disposed in various forms at a portion where stress to be applied to the substrate 100 is to be minimized, and accordingly, the abnormalities of the external connection member 600 disposed below the substrate 100 are to be minimized.

FIGS. 2A to 2E are top views of semiconductor packages 1000, 1000a, 1000b, 1000c, and 1000d according to embodiments of the inventive concept, wherein a sealing member and a wire are omitted for convenience of understanding. Hereinafter, for convenience of description, the description already made with reference to FIG. 1 will be concisely repeated or omitted.

Referring to FIG. 2A, in the semiconductor package 1000 according to this embodiment, the stress buffer layer 400 may be disposed at two edge parts of the substrate 100 (e.g., opposite edge parts) at two sides (e.g., opposite sides) of the second semiconductor chip 300 in a first direction (x direction). The stress buffer layer 400 may include a rectangular structure that is long in a second direction (e.g., extends lengthwise in a y direction) along both edges of the substrate 100 as shown in FIG. 2A. However, a structure of the stress buffer layer 400 is not limited to the rectangular structure or the particular edges of the substrate 100 shown.

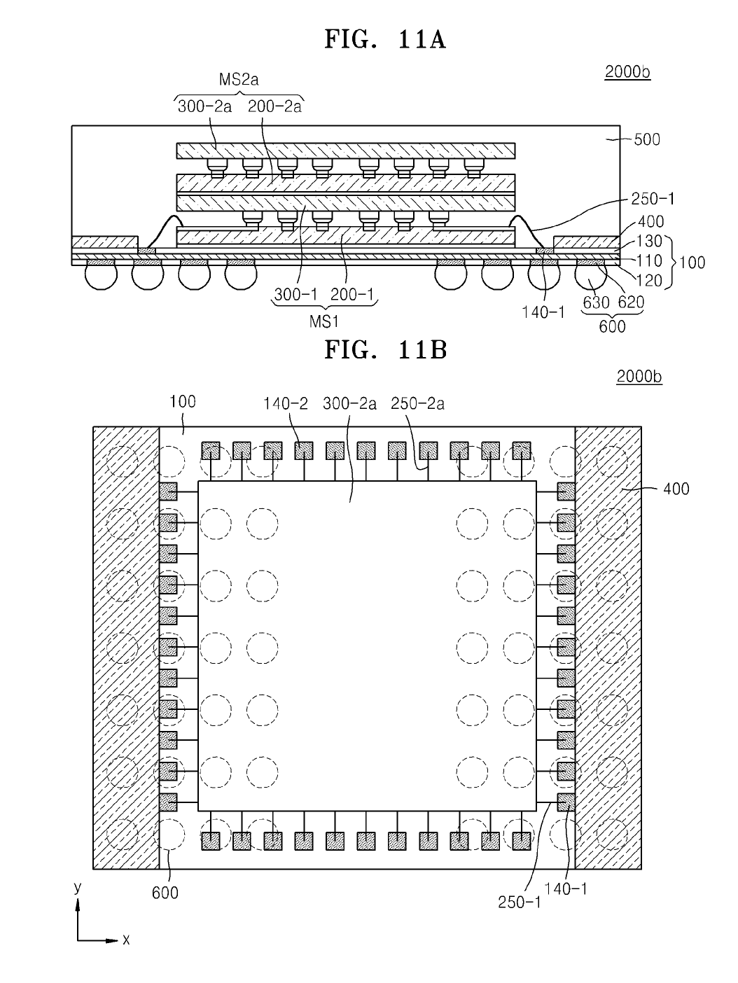

As a reference, although not shown in FIG. 2A, the first semiconductor chip 200 is disposed below the second semiconductor chip 300 (refer to FIG. 1). In addition, a plurality of wires (refer to FIGS. 1 and 11B) for electrically connecting the first semiconductor chip 200 to the substrate 100 may be disposed at the both sides of the second semiconductor chip 300 in the first direction. Of course, the plurality of wires may include wires for electrically connecting the second semiconductor chip 300 to the substrate 100. The external connection member 600 is drawn as a plurality of dotted circles by considering that the external connection members 600 are hidden by the substrate 100, the first and second semiconductor chips 200 and 300, and the stress buffer layer 400 and are not viewed. The number of external connection members 600 may vary according to a wiring structure of the substrate 100 or types or the number of semiconductor chips included in the semiconductor package 1000.

As described above, due to the CTE difference between the substrate 100 and the sealing member 500, stress applied to the substrate 100 may be greater at an edge part of the substrate 100 than a central part of the substrate 100. Therefore, like the semiconductor package 1000 according to the current embodiment, by disposing the stress buffer layer 400 at the both edge parts of the substrate 100 in the first direction, stress to be applied to the both edge parts of the substrate 100 may be buffered, and accordingly, the bending of the substrate 100 and the failure of the external connection member 600 disposed below the substrate 100 may be minimized.

Referring to FIG. 2B, unlike the semiconductor package 1000 of FIG. 2A, in the semiconductor package 1000a according to the current embodiment, a stress buffer layer 400a may be disposed at both edge parts of the substrate 100 at both sides of the second semiconductor chip 300 in the second direction (y direction). The stress buffer layer 400a may have a rectangular structure that is long in the first direction (x direction) along top and bottom edges of the substrate 100, when viewed as shown in FIG. 2B. However, a structure of the stress buffer layer 400a is not limited to the rectangular structure.

Stated differently, as can bee seen from FIGS. 2A and 2B, in one embodiment, (FIG. 2A), buffer structures extend lengthwise in a direction such each one covers a group of external connection members 600 extending substantially throughout the length of the buffer structure, with no gaps therebetween groups of external connection members 600. In another embodiment (FIG. 2B, buffer structures extend lengthwise in a direction such that they cover a plurality of external connection members 600 and there is a gap between groups of external connection members 600 extending along the direction of each buffer structure.

In the semiconductor package 1000a according to the embodiment of FIG. 2B, a width of the substrate 100 in the first direction (x direction) may not be sufficiently wider than widths of the first and second semiconductor chips 200 and 300. In addition, a plurality of wires (not shown) may be disposed at left and right edge parts of the first direction along the second direction. Accordingly, since a space is insufficient at the left and right edge parts of the substrate 100 in the first direction, the stress buffer layer 400a may be disposed at opposite edge parts (e.g., the top and bottom edge parts as shown the example of FIG. 2B) of the substrate 100 in the second direction.

Stress applied to the substrate 100 may be generated relatively largely at top and bottom edge parts of the substrate 100 in the second direction according to a structure of the sealing member 500 included in the semiconductor package 1000a. For example, in the shown structure of the semiconductor package 1000a, a contact portion between the left and right edge parts of the substrate 100 in the first direction and the sealing member 500 is relatively narrow, and a contact portion between the top and bottom edge parts of the substrate 100 in the second direction and the sealing member 500 is relatively wide, and thus, relatively large stress may be applied to the top and bottom edge parts of the substrate 100 in the second direction.

Accordingly, in the structure of the semiconductor package 1000a according to the current embodiment, by disposing the stress buffer layer 400a at the top and bottom edge parts of the substrate 100 in the second direction, stress to be applied to the top and bottom edge parts of the substrate 100 in the second direction may be buffered. As a result, the bending of the substrate 100 and the failure of the external connection member 600 disposed below the substrate 100 may be minimized. However, in the semiconductor package 1000 of FIG. 2A, the upward (a direction protruding from the paper) bending of both ends of the substrate 100 in the first direction may be prevented, and accordingly the failure of the external connection member 600 disposed below the substrate 100 may be prevented, but in the semiconductor package 1000a according to the current embodiment, the upward bending of both ends of the substrate in the second direction may be prevented, and accordingly the failure of the external connection member 600 disposed below the substrate 100 may be prevented.

Referring to FIG. 2C, unlike the semiconductor package 1000 or 1000a of FIG. 2A or 2B, in the semiconductor package 1000b according to the current embodiment, a stress buffer layer 400b may be disposed at four edge parts of the substrate 100 at four sides of the second semiconductor chip 300. The stress buffer layer 400b may have a rectangular ring structure that has a predetermined width along four side edge parts of the substrate 100. The stress buffer layer 400b may be formed as a one body in a structure surrounding the second semiconductor chip 300. A structure of the stress buffer layer 400b is not limited to the rectangular ring structure. For example, the stress buffer layer 400b may be formed in a form surrounding the second semiconductor chip 300 so as to include partially curved parts, for example, at inner or outer portions (e.g., corner portions) of the stress buffer layer 400b.

The stress buffer layer 400b is not limited to the one-body type of the rectangular ring structure and may be formed in a separated structure. For example, the stress buffer layer 400b may be formed in a rectangular structure that is long at each of the four side edge parts of the substrate 100, wherein the four rectangles are separated from each other. In detail, the stress buffer layer 400b may include left and right stress buffer layers disposed at the left and right edge parts of the substrate 100 and top and bottom stress buffer layers disposed at the top and bottom edge parts of the substrate 100. The left and right stress buffer layers may extend to the top and bottom edge parts of the substrate 100, but the top and bottom stress buffer layers may not extend to the left and right edge parts of the substrate 100 due to the presence of the left and right stress buffer layers.

According to circumstances, the top and bottom stress buffer layers may be disposed at the top and bottom edge parts of the substrate 100, and the left and right stress buffer layers may be disposed at the left and right edge parts of the substrate 100 between the top and bottom edge parts of the substrate 100. Alternatively, the stress buffer layer 400b may include the top, bottom, left, and right stress buffer layers so as for only one end part of each of the top, bottom, left, and right stress buffer layers to extend to the top, bottom, left, or right edge of the substrate 100.

In the semiconductor package 1000b according to the current embodiment, a width of the substrate 100 in the first direction (x direction) and a width of the substrate 100 in the second direction (y direction) may be sufficiently wider than those of the second semiconductor chip 300. Accordingly, the stress buffer layer 400b may be disposed at all of the left and right edge parts of the substrate 100 in the first direction and the top and bottom edge parts of the substrate 100 in the second direction.

In the structure of the semiconductor package 1000b according to the current embodiment, a contact portion between the left and right edge parts of the substrate 100 in the first direction and the sealing member 500 is relatively wide, and a contact portion between the top and bottom edge parts of the substrate 100 in the second direction and the sealing member 500 is also relatively wide. Accordingly, if the stress buffer layer 400b does not exist, relatively large stress may be applied to all of the left and right edge parts of the substrate 100 in the first direction and the top and bottom edge parts of the substrate 100 in the second direction.

In the structure of the semiconductor package 1000b according to the current embodiment, the stress buffer layer 400b may be disposed the four side edge parts of the substrate 100 in a form surrounding the second semiconductor chip 300 so as to cover all of the left and right edge parts of the substrate 100 in the first direction and the top and bottom edge parts of the substrate 100 in the second direction. Accordingly, stress to be applied to the left and right edge parts of the substrate 100 in the first direction and the top and bottom edge parts of the substrate 100 in the second direction may be buffered. As a result, the failure that the substrate 100 is bent upwards at both ends of the first direction and both ends of the second direction and the failure occurring at the external connection member 600 disposed below the substrate 100 may be minimized.

Many embodiments depicted herein show a stress buffer structure or multiple stress buffer structures extending at an edge part of a substrate all the way to the edge of the substrate. However, this is only one example. In certain embodiments, a stress buffer structure may be formed on an edge part of a substrate but may not extend all the way to the edge of the substrate. For example, a stress buffer structure that covers a plurality of external connection members 600 may have a width that extends to cover all or most of outer-most external connection members 600, and the structure may extend slightly past the outer-most connection members 600, but without extending all the way to the edge of the substrate.

Referring to FIG. 2D, in the semiconductor package 1000c, a stress buffer layer 400c may have a structure that is similar to a structure of the stress buffer layers 400 and 400a in the semiconductor packages 1000 and 1000a of FIGS. 2A and 2B. For example, the stress buffer layer 400c may be formed at the left and right edge parts of the substrate 100 in the first direction and the top and bottom edge parts of the substrate 100 in the second direction. However, as shown in FIG. 2D, the stress buffer layer 400c formed at the top and bottom edge parts of the substrate 100 in the second direction is not formed along the entire edge parts and may be formed, for example, only at a portion where the external connection members 600 are disposed. As such, the stress buffer layer 400c may include stress buffer structures formed at left and right ends of each of the top and bottom edge parts of the substrate 100.

In the semiconductor package 1000c according to the current embodiment, a width of the substrate 100 in the first direction (x direction) and a width of the substrate 100 in the second direction (y direction) may be sufficiently wider than those of the second semiconductor chip 300. Accordingly, the stress buffer layer 400c may be disposed at all of the left and right edge parts of the substrate 100 in the first direction and the top and bottom edge parts of the substrate 100 in the second direction.

Similarly to the structure of the semiconductor package 1000b of FIG. 2C, in the structure of the semiconductor package 1000c according to the current embodiment, a contact portion between the left and right edge parts of the substrate 100 in the first direction and the sealing member 500 may be relatively wide, and a contact portion between the top and bottom edge parts of the substrate 100 in the second direction and the sealing member 500 may also be relatively wide (e.g., the contact portions may extend to a width greater than the width of at least one external connection member 600, and in some cases at least as wide as a width between one end of one external connection member 600 to at least a middle of a second adjacent external connection member 600). Accordingly, if the stress buffer layer 400c does not exist, relatively large stress may be applied to all of the left and right edge parts of the substrate 100 in the first direction and the top and bottom edge parts of the substrate 100 in the second direction.

As shown in FIG. 2D, the external connection members 600 may be disposed along the second direction so as to be adjacent to the left and right edges of the substrate 100 in the first direction and may not be disposed at a portion of the top and bottom edge parts of the substrate 100 in the second direction. For example, the external connection members 600 may not be disposed at a central part, and may only be disposed at sides of the top and bottom edge parts of the substrate 100. When stress is applied to edge parts of the substrate 100, the substrate 100 is bent, and accordingly, the failure occurs at the external connection member 600 disposed below the substrate 100 as described above. However, for the portion where the external connection member 600 is not disposed, even if the substrate 100 is slightly bent, the failure at the external connection members 600 does not occur.

Therefore, in the structure of the semiconductor package 1000c according to the current embodiment, the stress buffer layer 400c may be formed at most edge parts of the substrate 100 and may not be formed at edge parts of the portion where the external connection members 600 are not disposed. This may reduce the amount of material used for the stress buffer layer 400c. For example, the stress buffer layer 400c may not be formed at central portions of the top and bottom edge parts of the substrate 100 where the external connection member 600 is not disposed. In addition, the stress buffer layer 400c may be formed at both ends of the top and bottom edge parts of the substrate 100, and due to the stress buffer layer 400c, stress applied to the central portions of the top and bottom edge parts of the substrate 100 may also be somewhat alleviated.

In the structure of the semiconductor package 1000c according to the current embodiment, the stress buffer layer 400c may be disposed at edge parts of the substrate 100 in correspondence with the portions where the external connection members 600 are disposed. Alternatively, the stress buffer layer 400c may be formed with predetermined lengths along the edges of the substrate 100 and may be disposed so as for each part thereof to cover some external connection members 600. However, in the structure of the semiconductor package 1000c according to the current embodiment, a structure of the stress buffer layer 400c is not limited to the structure described above. For example, a plurality of stress buffer structures 400c may be disposed along each edge of the substrate 100, and each of the plurality of stress buffer structures 400c may correspond to each external connection member 600. Alternatively, the stress buffer layer 400c may be disposed at the edge parts of the substrate 100 so as to correspond to at least one of a plurality of external connection members 600 disposed below the substrate 100.

In the structure of the semiconductor package 1000c according to the current embodiment, by disposing the stress buffer layer 400c at the edge parts of the substrate 100 so as to correspond to only potions where the external connection members 600 are disposed, the bending of the substrate 100 may be prevented, and the failure of the external connection members 600 disposed below the substrate 100 may also be efficiently prevented.

Referring to FIG. 2E, in a semiconductor package 1000d according to one embodiment, the stress buffer layer 400 may have the same structure as the stress buffer layer 400 in the semiconductor package 1000 of FIG. 2A. However, as shown in FIG. 2E, in the semiconductor package 1000d according to the current embodiment, the external connection members 600 may be disposed on the entire lower surface of the substrate 100. For example, the external connection member 600 may be disposed along the left and right sides of the substrate 100 in the first direction and may not be disposed at the central part of the substrate 100 in the semiconductor packages 1000, 1000a, 1000b, and 1000c. However, in the semiconductor package 1000d according to the current embodiment, the external connection members 600 may be disposed on the entire lower surface of the substrate 100 regardless of the central part and the edge parts of the substrate 100.

As a reference, the arrangement of the external connection members 600 may variously vary according to a semiconductor package type, specifically, to an internal wiring pattern of the substrate 100. For example, the external connection members 600 may have various arrangement structures, such as a structure disposed on the entire lower surface of the substrate 100, a structure disposed along both edge parts of the substrate 100, a structure disposed so as to pass through the central part of the substrate 100, a structure disposed at the central part of the substrate 100, a structure surrounding four side edge parts of the substrate 100, and the like.

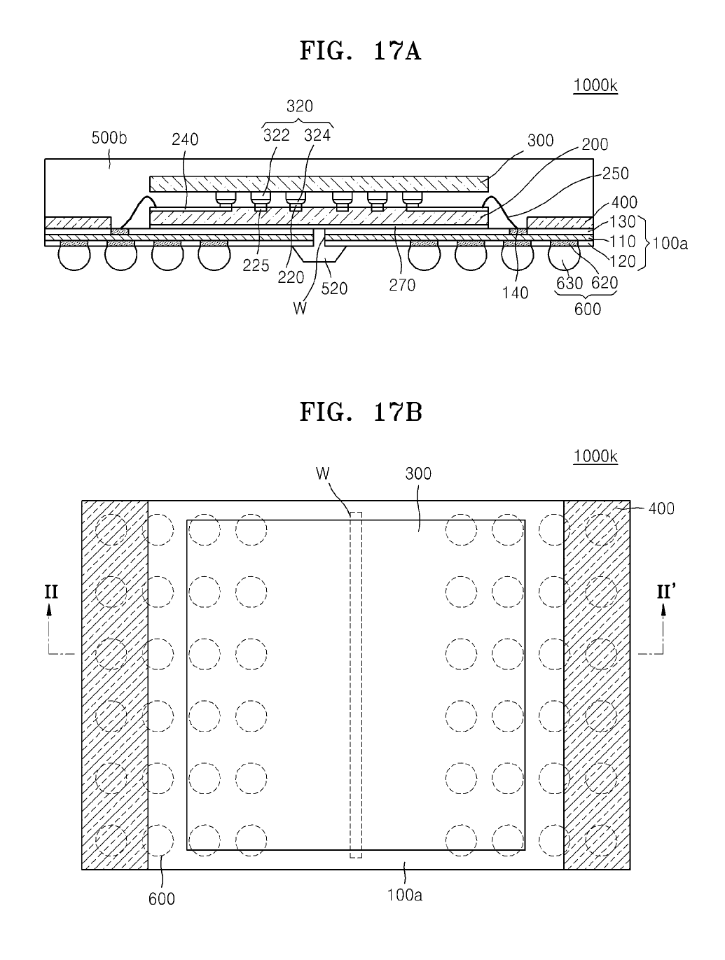

In detail, when a wiring pattern is formed inside the substrate 100 so as to use the entire lower surface of the substrate 100, and a corresponding wiring pattern is also formed on a board, such as a module substrate on which the substrate 100 is mounted, the external connection members 600 may be disposed on the entire lower surface of the substrate 100. When a wiring pattern of the board is somewhat standardized, and a wiring pattern of the substrate 100 is formed so as to correspond to the wiring pattern of the board, the external connection members 600 may be disposed at the left and right edge parts of the substrate 100 in the first direction and disposed along the second direction. As shown in FIGS. 17A and 17B, when an EMC window is formed on the substrate 100, and a portion of an EMC is formed so as to protrude from the lower surface of the substrate 100, the external connection members 600 cannot be formed at a part of the EMC window, and thus, the external connection members 600 may be disposed along both parts based on the EMC window.

FIG. 3 is a cross-sectional view of a semiconductor package 1000e according to another embodiment of the inventive concept. For convenience of description, the above description will be concisely repeated or omitted.

Referring to FIG. 3, the semiconductor package 1000e according to the current embodiment may be similar to the semiconductor package 1000 of FIG. 1 except for a structure of a sealing member 500a. For example, in the semiconductor package 1000e according to the current embodiment, the sealing member 500a may expose the inactive surface NACT of the second semiconductor chip 300. Even when the inactive surface NACT of the second semiconductor chip 300 is exposed, the exposure of the inactive surface NACT of the second semiconductor chip 300 may not influence the devices inside the second semiconductor chip 300.

In a structure of the semiconductor package 1000e according to the current embodiment, by forming the sealing member 500a so as to expose the upper surface of the second semiconductor chip 300, a height of the semiconductor package 1000e may be minimized, and accordingly, the sealing member 500a may contribute to size reduction and thinness of the semiconductor package 1000e. Of course, even in the semiconductor package 1000e according to the current embodiment, by disposing the stress buffer layer 400 at the edge parts of the substrate 100, stress to be applied to the substrate 100 may be buffered, and accordingly, the bending of the substrate 100 may be prevented, and the failure of the external connection member 600 disposed below the substrate 100 may be prevented.

As in the semiconductor package 1000e according to the current embodiment, the structure of the sealing member 500a which exposes the upper surface of the uppermost semiconductor chip, i.e., the second semiconductor chip 300, may be formed by an exposed-MUF (e-MUF) process. As a reference, the e-MUF process may indicate a process of exposing the upper surface of the uppermost semiconductor chip from a sealing member in an MUF process of forming both an underfill member and the sealing member. The e-MUF process may indicate a process of adjusting an internal height of a mold so as to almost match the upper surface of the uppermost semiconductor chip so that a sealing member is not formed on the upper surface of the uppermost semiconductor chip when the sealing member is injected.

The structure of the semiconductor package 1000e may be implemented by a grinding process besides the e-MUF process. For example, after forming the sealing member 500 so as to cover the upper surface of the uppermost semiconductor chip, i.e., the second semiconductor chip 300, as shown in FIG. 1, the semiconductor package 1000e according to the current embodiment may be implemented by removing an upper part of the sealing member 500 by the grinding process to expose the upper surface of the second semiconductor chip 300. According to circumstances, after stacking the second semiconductor chip 300 in a relatively thick state on the first semiconductor chip 200, both the second semiconductor chip 300 and the sealing member 500 may become thin.

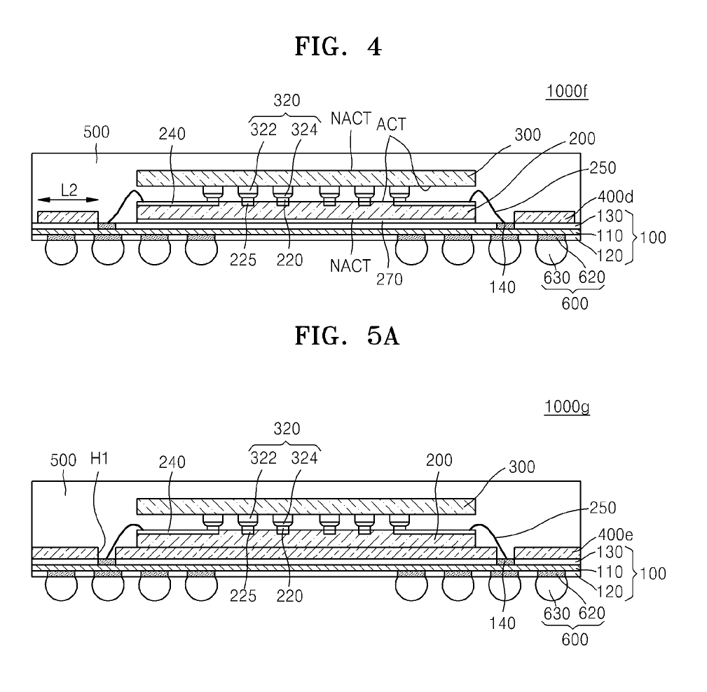

FIG. 4 is a cross-sectional view of a semiconductor package 1000f according to another embodiment of the inventive concept. For convenience of description, the above description will be concisely repeated or omitted.

Referring to FIG. 4, the semiconductor package 1000f according to the current embodiment may be similar to the semiconductor package 1000 of FIG. 1 except for a structure of a stress buffer layer 400d. For example, in the semiconductor package 1000f according to the current embodiment, side surfaces of the stress buffer layer 400d may be surrounded by the sealing member 500 so as not to be exposed to the outside. As described above, by completely sealing the stress buffer layer 400d by the sealing member 500, the first and second semiconductor chips 200 and 300 inside the sealing member 500 may be relatively safely protected from external physical and chemical damages. When a size of the semiconductor package 1000f according to the current embodiment is the same as that of the semiconductor package 1000 of FIG. 1, the stress buffer layer 400d may have a width of a second length L2 so as for the entire stress buffer layer 400d to be covered by the sealing member 500, and the second length L2 may be shorter than the first length L1 in the semiconductor package 1000 of FIG. 1.

In the semiconductor package 1000f according to the current embodiment, the stress buffer layer 400d may be formed in a rectangular structure at both edge parts of the substrate 100 as shown in FIG. 2A except for the fact that the entire stress buffer layer 400d is covered by the sealing member 500. As shown, rather than a side surface of the stress buffer layer 400d being coplanar with side surfaces of the substrate 100 and the sealing member, the side surface of the stress buffer layer 400d is covered with the sealing member 500 and contacts the sealing member 500. The stress buffer layer 400d is not limited to the structure of FIG. 2A and may be disposed and formed at edge parts of the substrate in various structures as shown in FIGS. 2B to 2D. Furthermore, the stress buffer layer 400d may be formed at edge parts of the substrate 100 in correspondence with at least one of a plurality of external connection members 600 disposed below the substrate 100 (e.g., to vertically overlap with the one or plurality of external connection members 600). Thus, the stress buffer layer 400d in the various structures may be formed so as for the entire stress buffer layer 400d to be covered by the sealing member 500.

Even in the structure of the semiconductor package 1000f according to the current embodiment, by disposing the stress buffer layer 400d at edge parts of the substrate 100, stress to be applied to the substrate 100 may be buffered, and accordingly, the bending of the substrate 100 may be prevented, and the failure of the external connection member 600 disposed below the substrate 100 may be prevented.

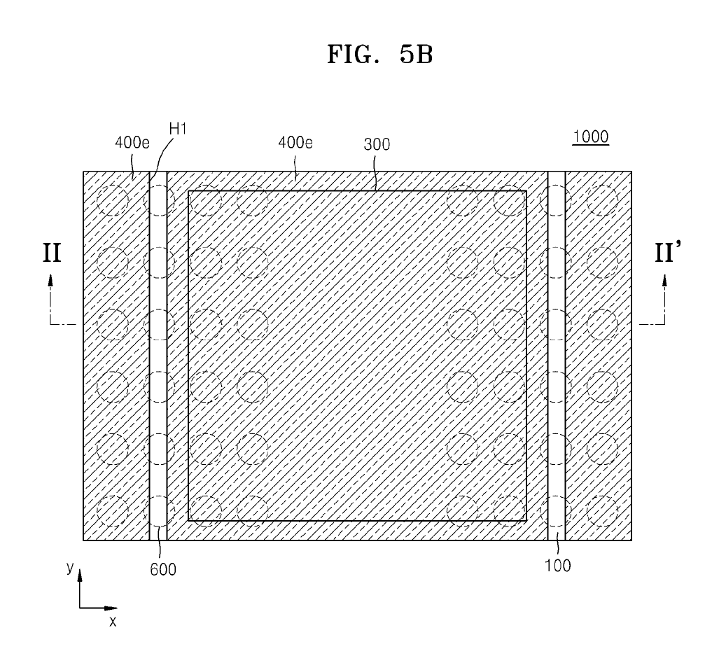

FIGS. 5A and 5B are a cross-sectional view and a top view of a semiconductor package 1000g according to embodiments of the inventive concept. For convenience of description, the above description will be concisely repeated or omitted.

Referring to FIGS. 5A and 5B, unlike the embodiments described above, in the semiconductor package 1000g according to the current embodiment, a stress buffer layer 400e may be formed on nearly the entire surface of the substrate 100. Accordingly, the first semiconductor chip 200 may be formed on the stress buffer layer 400e. If the stress buffer layer 400e is formed of an adhesive material, the first semiconductor chip 200 may be directly adhered and fixed to the stress buffer layer 400e without a separate adhesive member. Of course, the first semiconductor chip 200 may be adhered and fixed onto the stress buffer layer 400e through a separate adhesive member, e.g., a DAF.

Since the first semiconductor chip 200 is electrically connected to the substrate pad 140 through the wire 250, holes H1 for exposing the substrate pad 140 may be formed in the stress buffer layer 400e. The holes H1 may be formed, for example, in a form of exposing each substrate pad 140. Alternatively, only two holes H1 may be formed at both edge parts of the substrate 100, and each of the two holes H1 may be formed so as to have a drain form of exposing the entire substrate pads 140 disposed at a corresponding edge part.

By forming the stress buffer layer 400e on almost the entire surface of the substrate 100 (e.g., on all four edge parts of the substrate 100 as well as the portion of the substrate 100 underneath the semiconductor chip 200), the substrate 100 may be more free from stress generated due to a CTE difference with the sealing member 500 and/or the first and second semiconductor chips 200 and 300 than the embodiments described above. Thus, the stress buffer layer 400e disposed on nearly the entire surface of the substrate 100 may contribute more to a decrease in a modulus and an increase in a CTE of the substrate 100 than the embodiments described above by making the substrate 100 free from the sealing member 500 and/or the first and second semiconductor chips 200 and 300. The decrease in the modulus and the increase in the CTE of the substrate 100 due to the stress buffer layer 400e of the structure described above may contribute to a decrease in stress to the substrate, thereby preventing the bending of the substrate 100. Accordingly, the failure of the external connection member 600 disposed below the substrate 100 may be minimized.

FIG. 6 is a circuit diagram showing an electrical connection relationship of the first and second semiconductor chips 200 and 300 in the semiconductor package 1000 of FIG. 1. For convenience of description, the above description will be concisely repeated or omitted.

Referring to FIG. 6, the first and second semiconductor chips 200 and 300 include first input/output pads 210 and second input/output pads 310, respectively, which may respectively connected to a first input/output buffer circuit 280 and a second input/output buffer circuit 380. The first input/output buffer circuit 280 and the second input/output buffer circuit 380 may be connected to an internal circuit 205 of the first semiconductor chip 200 and an internal circuit 305 of the second semiconductor chip 300, respectively.

A first terminal 290 is provided between the internal circuit 205 and the first input/output pads 210 of the first semiconductor chip 200, a second terminal 390 is provided between the internal circuit 305 and the second input/output pads 310 of the second semiconductor chip 300, and the first terminal 290 and the second terminal 390 may be electrically connected to each other. A block in front of an input receiver may be a pad connectable to the outside.

When the second input/output pads 310 receive a signal DQO from the substrate pad 140 of the substrate 100, the signal DQO may be delivered to the internal circuit 205 of the first semiconductor chip 200 or the internal circuit 305 of the second semiconductor chip 300 according to a chip selection signal CS. If the chip selection signal CS selects the second semiconductor chip 300, the second semiconductor chip 300 may transmit and receive data to and from the substrate 100 along a route of the second input/output pads 310, the second input/output buffer circuit 380, the second terminal 390, and the internal circuit 305.

If the chip selection signal CS selects the first semiconductor chip 200, the first semiconductor chip 200 may transmit and receive data to and from the substrate 100 along a route of the second input/output pads 310, the second input/output buffer circuit 380, the second terminal 390, the first terminal 290, and the internal circuit 205. Therefore, in this case, the first input/output pads 210 and the first input/output buffer circuit 280 may be disabled.

As described above, the first semiconductor chip 200 may transmit and receive a signal and/or data to and from the substrate 100 by passing through the second semiconductor chip 300. For example, the first semiconductor chip 200 may transmit and receive a signal and/or data to and from the substrate 100 without using the first input/output pads 210 and the first input/output buffer circuit 280 in the first semiconductor chip 200.

As a reference, like the second semiconductor chip 300, a semiconductor chip capable of transmitting and receiving data through input/output pads and an input/output buffer circuit thereof is called a master chip, and like the first semiconductor chip 200, a semiconductor chip capable of transmitting and receiving a signal and/or data through input/output pads and an input/output buffer circuit of another semiconductor chip is called a slave chip.

Hereinafter, a wiring connection relationship in a structure in which the first semiconductor chip 200 and the second semiconductor chip 300 are stacked in a mirror form through flip-chip bonding will be described.

FIGS. 7A and 7B are top views showing a connection relationship of pads and bumps in the first and second semiconductor chips 200 and 300 on the basis of the circuit diagram of FIG. 6. For convenience of description, the above description will be concisely repeated or omitted.

Referring to FIG. 7A, the first semiconductor chip 200 may be disposed on the substrate 100, as the closest chip to the substrate. The first input/output pads 210 symmetrically arranged in two lines adjacent to a center line C of the first semiconductor chip 200 may be disposed on the active surface ACT of the first semiconductor chip 200. The first input/output pads 210 may be arranged in one line or two or more lines. When the first input/output pads 210 are arranged in an even number of lines, the first input/output pads 210 may be symmetrically arranged on the basis of the center line C. Alternatively, even when the first input/output pads 210 are arranged in an even number of lines, the first input/output pads 210 may be asymmetrically arranged.

Each of first rewirings 240 may electrically connect a first bump 220 to a bonding pad 230. As a reference, the bonding pad 230 is omitted and not shown in FIGS. 1 and 3 to 5B. In addition, the first rewirings 240 may correspond to the rewirings 240 in FIGS. 1 and 3 to 5B.

As shown in FIG. 7A, the bonding pads 230 may be electrically connected to corresponding substrate pads 140 on the substrate 100. For example, the bonding pads 230 may be electrically connected to the substrate pads 140 through wires 250. However, it is not excluded that the bonding pads 230 are connected to the substrate pads 140 by another connection method, such as a flip-chip method.

As shown in FIG. 7A, the first rewirings 240 may extend not to cross the center line C of the first semiconductor chip 200 and may connect first bumps 220 and bonding pads 230 to each other. Although eight wires 250 for connecting the first semiconductor chip 200 are shown according to FIG. 7A, the eight wires 250 are only for convenience of understanding, and each of the number of wires 250, the number of corresponding first bumps 220, and the number of corresponding bonding pads 230 may be of course greater than 8. Although it is shown in FIGS. 1 and 3 to 5B that the first rewirings 240 are exposed on the first semiconductor chip 200, the first rewirings 240 may not be exposed by being covered by a passivation layer (not shown).

In FIG. 7A, 260a may indicate bumps electrically connected to the internal circuit 205 of the first semiconductor chip 200.

Referring to FIG. 7B, the second input/output pads 310 symmetrically arranged in two lines adjacent to a center line C of the second semiconductor chip 300 may be disposed on the active surface ACT of the second semiconductor chip 300. Of course, the second input/output pads 310 may also be arranged in one line or three or more lines.

A second rewiring 340 may be provided for each of the second input/output pads 310. The second rewirings 340 may extend not to cross the center line C of the second semiconductor chip 300. As a reference, the second input/output pads 310 and the second rewirings 340 are omitted and not shown in FIGS. 1 and 3 to 5B.

The second rewirings 340 may extend from the second input/output pads 310 to second bumps 320 disposed at both edge parts. Accordingly, the second rewirings 340 may electrically connect the second input/output pads 310 to the second bumps 320. The second bumps 320 may be physically and electrically connected to the corresponding first bumps 220 provided on the first semiconductor chip 200 of FIG. 7A. Therefore, the first bumps 220 and the second bumps 320 may be disposed so as to overlap each other at same positions in consideration of the physical and electrical connection therebetween when the active surfaces ACT of the first and second semiconductor chips 200 and 300 are stacked to face each other. As a reference, the second bumps 320 may correspond to the second bumps disposed at both edges in FIGS. 1 and 3 to 5B.

Referring to FIGS. 7A and 7B, when the first bumps 220 and the second bumps 320 are coupled to each other by stacking the second semiconductor chip 300 on the first semiconductor chip 200 by a flip-chip method, an input/output route from a substrate pad 140 of the substrate 100 to an second input/output pad 310 may be configured not to cross the center line C of the second semiconductor chip 300.

The first semiconductor chip 200 may include a plurality of third bumps 260a electrically connected to the internal circuit 105 of the first semiconductor chip 200. The plurality of third bumps 260a may correspond to first bumps 220 disposed at the center parts in FIGS. 1 and 3 to 5B. In addition, the second semiconductor chip 300 may include a plurality of fourth bumps 360a electrically connected to the internal circuit 305 of the second semiconductor chip 300. The plurality of fourth bumps 360a may correspond to second bumps 320 disposed at the center parts in FIGS. 1 and 3 to 5B.

The plurality of third bumps 260a and the plurality of fourth bumps 360a corresponding to the plurality of third bumps 260a may be disposed at positions where the plurality of third bumps 260a and the plurality of fourth bumps 360a are coupled so as to overlap each other when the active surfaces ACT of the first and second semiconductor chips 200 and 300 are stacked to face each other. Therefore, the plurality of third bumps 260a and the plurality of fourth bumps 360a corresponding to the plurality of third bumps 260a may be electrically connected to each other.

As such, position and connection relationships of pads, rewirings, and bumps on respective semiconductor chips may be formed in a mirror-type stacking structure in which the first semiconductor chip 200 on the substrate 100 functions as a slave chip, and the second semiconductor chip 300 stacked on the first semiconductor chip 200 functions as a master chip. However, the structure of the semiconductor package 1000 according to the current embodiment is not limited to the above-described position and connection relationships of pads, rewirings, and bumps on respective semiconductor chips. For example, in a structure of a semiconductor package having a mirror-type stacking structure, position and connection relationships of pads, rewirings, and bumps on respective semiconductor chips may be variously modified. As a reference, the mirror-type stacking structure may indicate a structure in which two semiconductor chips having a same internal circuit are stacked in a flip-chip method so as to face each other and become a mirror phase for each other.

The semiconductor package 1000 according to the current embodiment may be implemented in a mirror-type stacking structure in which the first semiconductor chip 200 functions as a master chip, and the second semiconductor chip 300 stacked on the first semiconductor chip 200 functions as a slave chip. When the first semiconductor chip 200 is a master chip, the first input/output pads 210 on the first semiconductor chip 200 may be connected to bonding pads through first rewirings. However, due to the limitation of the mirror-type stacking structure, the first rewirings may be formed so as to cross the center line C of the first semiconductor chip 200, and accordingly, a structure of the semiconductor package 1000 may be a little more complicated than the above-described embodiments.

FIG. 8 is a cross-sectional view of a semiconductor package 2000 according to another embodiment of the inventive concept. For convenience of description, the above description will be concisely repeated or omitted.

Referring to FIG. 8, the semiconductor package 2000 according to the current embodiment may include two pairs of mirror-type stacking structures MS1 and MS2 on the substrate 100. A first mirror-type stacking structure MS1 may include a first semiconductor chip 200-1 and a second semiconductor chip 300-1, and a second mirror-type stacking structure MS2 may include a third semiconductor chip 200-2 and a fourth semiconductor chip 300-2.

The first mirror-type stacking structure MS1 may be stacked on the substrate 100 through a first adhesive member 270-1. The first mirror-type stacking structure MS1 is the same as the mirror-type stacking structure having the first and second semiconductor chips 200 and 300 in the semiconductor package 1000 of FIG. 1, and thus, a detailed description thereof is omitted.

The second mirror-type stacking structure MS2 may be stacked on the first mirror-type stacking structure MS1 through a second adhesive member 270-2. In more detail, the second mirror-type stacking structure MS2 may be implemented by stacking the third semiconductor chip 200-2 on an inactive surface of the second semiconductor chip 300-1 through the second adhesive member 270-2 and stacking the fourth semiconductor chip 300-2 on the third semiconductor chip 200-2 in a flip-chip method. The second adhesive member 270-2 may be the same as the first adhesive member 270-1. For example, the second adhesive member 270-2 may be a DAF.

The second mirror-type stacking structure MS2 is stacked on the second semiconductor chip 300-1 instead of the substrate 100. Accordingly, a second wire 205-2 for connecting the second mirror-type stacking structure MS2 and a substrate pad 140 may be longer than a first wire 205-1 for connecting the first mirror-type stacking structure MS1 and the substrate pad 140. For the others, the second mirror-type stacking structure MS2 may be almost the same as the first mirror-type stacking structure MS1. Therefore, a detailed description thereof is omitted.

Although it is shown in the semiconductor package 2000 according to the current embodiment that the first wire 205-1 of the first mirror-type stacking structure MS1 and the second wire 205-2 of the second mirror-type stacking structure MS2 are connected to one substrate pad 140, the semiconductor package 2000 according to the current embodiment is not limited to the connection relationship. For example, the first wire 205-1 of the first mirror-type stacking structure MS1 and the second wire 205-2 of the second mirror-type stacking structure MS2 may be connected to different substrate pads. In this case, the substrate pads may be arranged in two lines at both edge parts of the substrate 100, wherein a substrate pad in an inner line is connected to the first wire 205-1 of the first mirror-type stacking structure MS1, and a substrate pad in an outer line is connected to the second wire 205-2 of the second mirror-type stacking structure MS2. This connection relationship may be used to input/output data by using two channels. For example, the first mirror-type stacking structure MS1 may input/output data through a first channel, and the second mirror-type stacking structure MS2 may input/output data through a second channel.

The semiconductor package 2000 according to the current embodiment may implement a high-capacity and high-integration semiconductor package by including four semiconductor chips. In addition, even in the structure of the semiconductor package 2000 according to the current embodiment, by disposing the stress buffer layer 400 at edge parts of the substrate 100, stress to be applied to the substrate 100 may be buffered, and accordingly, the bending of the substrate 100 and the failure of the external connection member 600 disposed below the substrate 100 may be prevented. As shown, the stress buffer layer 400 may be at the same vertical level as a bottom-most chip of the semiconductor package 2000.

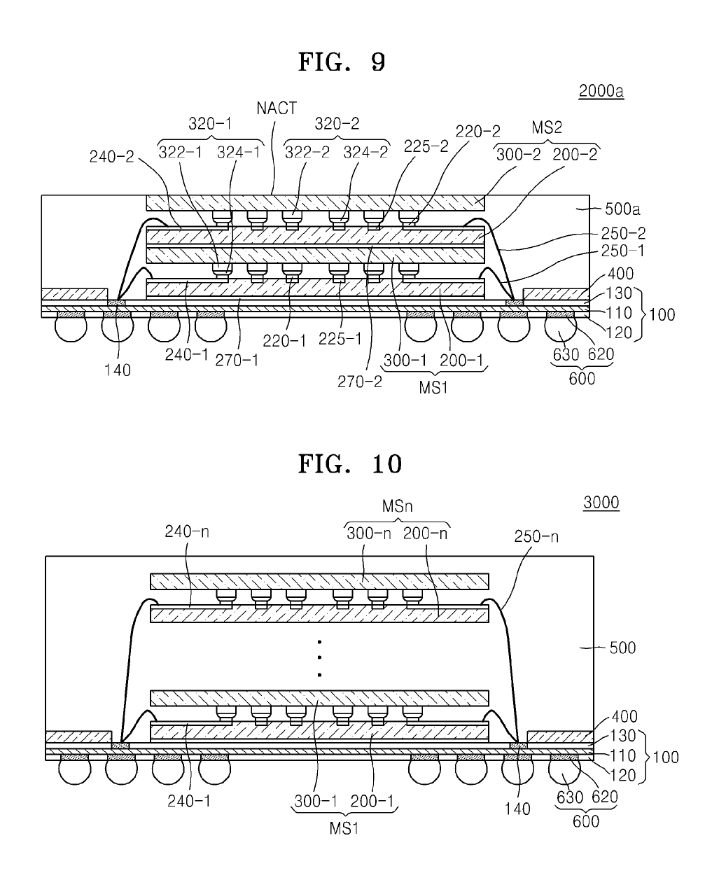

FIG. 9 is a cross-sectional view of a semiconductor package 2000a according to another embodiment of the inventive concept. For convenience of description, the above description will be concisely repeated or omitted.

Referring to FIG. 9, the semiconductor package 2000a according to the current embodiment may be similar to the semiconductor package 2000 of FIG. 8 except for a structure of a sealing member 500a. That is, in the semiconductor package 2000a according to the current embodiment, the sealing member 500a may expose an inactive surface NACT of the fourth semiconductor chip 300-2 of the second mirror-type stacking structure MS2. Even when the inactive surface NACT of the fourth semiconductor chip 300-2 is exposed, the exposure of the inactive surface NACT of the fourth semiconductor chip 300-2 may not influence the devices inside the fourth semiconductor chip 300-2 at all.

In a structure of the semiconductor package 2000a according to the current embodiment, by forming the sealing member 500a so as to expose the upper surface of the fourth semiconductor chip 300-2, a height of the semiconductor package 2000a may be minimized, and accordingly, the sealing member 500a may contribute to size reduction and thinness of the semiconductor package 2000a. As such, the structure of the sealing member 500a which exposes the upper surface of the uppermost semiconductor chip, i.e., the fourth semiconductor chip 300-2, may be implemented by an e-MUF process or a grinding process.

Even in the structure of the semiconductor package 2000a according to the current embodiment, by disposing the stress buffer layer 400 at edge parts of the substrate 100, stress to be applied to the substrate 100 may be buffered, and accordingly, the bending of the substrate 100 may be prevented, and the failure of the external connection member 600 disposed below the substrate 100 may be prevented.

FIG. 10 is a cross-sectional view of a semiconductor package 3000 according to another embodiment of the inventive concept. For convenience of description, the above description will be concisely repeated or omitted.

Referring to FIG. 10, the semiconductor package 3000 according to the current embodiment may include n pairs of mirror-type stacking structures MS1 to MSn on the substrate 100, wherein n is an integer that is 3 or greater. For example, in a structure of the semiconductor package 3000 according to the current embodiment, a first mirror-type stacking structure MS1 may include a first semiconductor chip 200-1 and a second semiconductor chip 300-1, a second mirror-type stacking structure MS2 may include a third semiconductor chip (not shown) and a fourth semiconductor chip (not shown), and an nth mirror-type stacking structure MSn may include a (2n−1)th semiconductor chip 200-n and a 2nth semiconductor chip 300-n.

Each of the first to nth mirror-type stacking structures MS1 to MSn may be the same as the mirror-type stacking structure having the first and second semiconductor chips 200 and 300 in the semiconductor package 1000 of FIG. 1. However, each of the second to nth mirror-type stacking structures MS2 to MSn may be stacked on a mirror-type stacking structure disposed therebelow instead of the substrate 100. In addition, an upper mirror-type stacking structure is farther from the substrate 100, and thus, the upper mirror-type stacking structure may have a longer wire connected to a substrate pad 140. The others have been described with respect to the semiconductor package 1000 of FIG. 1, and thus, a description thereof is omitted herein.

The semiconductor package 3000 according to the current embodiment may implement a high-capacity and high-integration semiconductor package by including six or more semiconductor chips. In addition, even in the structure of the semiconductor package 3000 according to the current embodiment, by disposing the stress buffer layer 400 at edge parts of the substrate 100, stress to be applied to the substrate 100 may be buffered, and accordingly, the bending of the substrate 100 and the failure of the external connection member 600 disposed below the substrate 100 may be prevented.

FIGS. 11A and 11B are a cross-sectional view and a top view of a semiconductor package 2000b according to another embodiment of the inventive concept. For convenience of description, the above description will be concisely repeated or omitted.

Referring to FIGS. 11A and 11B, the semiconductor package 2000b according to the current embodiment may include two pairs of mirror-type stacking structures MS1 and MS2a as in the semiconductor package 2000 of FIG. 8. However, a method of stacking the two pairs of mirror-type stacking structures MS1 and MS2a and a connection relationship between the two pairs of mirror-type stacking structures MS1 and MS2a and the substrate 100 may differ from the semiconductor package 2000 of FIG. 8.

For example, in the structure of the semiconductor package 2000 of FIG. 8, the first mirror-type stacking structure MS1 at the bottom and the second mirror-type stacking structure MS2a at the top may have a same stacking structure and may have a structure in which both the first wire 250-1 connected to the first mirror-type stacking structure MS1 and the second wire 250-2a connected to the second mirror-type stacking structure MS2a are connected to one substrate pad 140. In other words, the positions of the pads, rewirings, and bumps of the first semiconductor chip 200-1 and the third semiconductor chip 200-2 may be the same as each other, and in addition, the positions of the pads, rewirings, and bumps of the second semiconductor chip 300-1 and the fourth semiconductor chip 300-2 may be the same as each other.

However, in the semiconductor package 2000b according to the current embodiment, a first mirror-type stacking structure MS1 and a second mirror-type stacking structure MS2a at the top may be stacked in a mismatch structure by 90° or 270°. Accordingly, like the semiconductor package 1000 of FIG. 1, the first mirror-type stacking structure MS1 may be connected to first substrate pads 140-1 through first wires 250-1. However, since the second mirror-type stacking structure MS2a rotates based on the first mirror-type stacking structure MS1 by 90° or 270°, bonding pads (not shown) may be disposed on top and bottom edge parts of the second direction (y direction) along the first direction (x direction). In addition, second substrate pads 140-2 may be disposed on the substrate 100 at top and bottom edge parts of the substrate 100 along the first direction. Accordingly, second wires 250-2a for connecting the bonding pads and the second substrate pads 140-2 may be disposed on the top and bottom edge parts of the substrate 100 along the first direction.

The structure of the semiconductor package 2000b according to the current embodiment may be advantageous when the first mirror-type stacking structure MS1 and the second mirror-type stacking structure MS2a input/output data by using different channels. For example, if substrate pads corresponding to two channels are disposed only at both edge parts of the substrate 100, an arrangement area for the substrate pads may not be sufficiently secured. In addition, when it is considered that the stress buffer layer 400 is disposed at both edge parts of the substrate 100, it may be more difficult to secure a space for the substrate pads corresponding to the two channels. However, in the semiconductor package 2000b according to the current embodiment, an arrangement area for substrate pads corresponding to two channels may be sufficiently secured by forming substrate pads at four-side edge parts of the substrate 100.

FIG. 11A shows that first direction (x direction) widths of the first mirror-type stacking structure MS1 and the second mirror-type stacking structure MS2a are almost the same in the semiconductor package 2000b according to the current embodiment. FIG. 11A is under the assumption that the semiconductor package 2000b according to the current embodiment has a square structure in which a first direction width and a second direction width of semiconductor chips are the same. However, if the semiconductor chips have a rectangular structure instead of the square structure, in FIG. 11A, the semiconductor package 2000b according to the current embodiment may have a structure in which side surfaces of semiconductor chips in any one of the first mirror-type stacking structure MS1 and the second mirror-type stacking structure MS2a protrude based on side surfaces of semiconductor chips in the other one of the first mirror-type stacking structure MS1 and the second mirror-type stacking structure MS2a.

The semiconductor package 2000b according to the current embodiment may be advantageous to secure substrate pads in a semiconductor package structure using multiple channels. In addition, by disposing the stress buffer layer 400 at edge parts of the substrate 100, stress to be applied to the substrate 100 may be still buffered, and accordingly, the bending of the substrate 100 may be prevented, and the failure of the external connection member 600 disposed below the substrate 100 may be prevented.

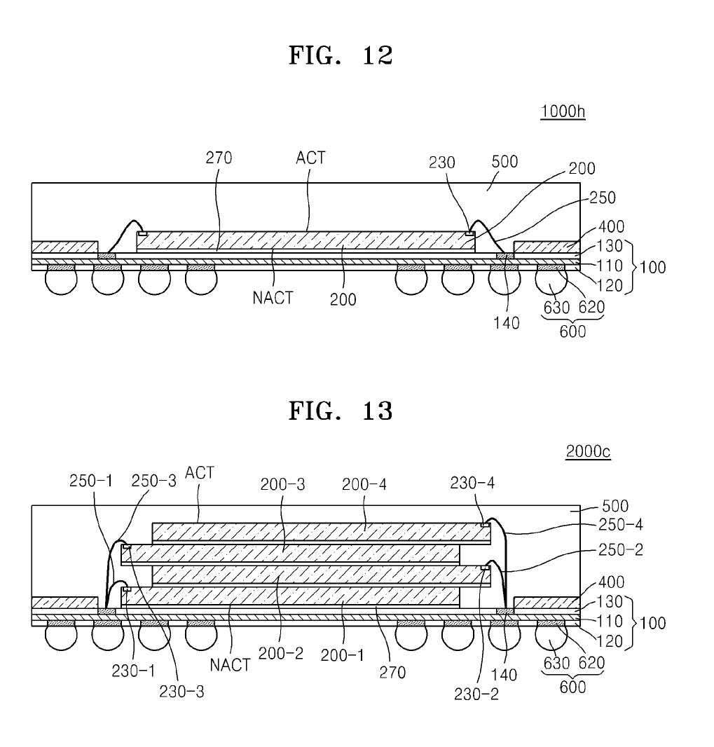

FIG. 12 is a cross-sectional view of a semiconductor package 1000h according to another embodiment of the inventive concept. For convenience of description, the above description will be concisely repeated or omitted.

Referring to FIG. 12, the semiconductor package 1000h according to the current embodiment may include one semiconductor chip 200 on the substrate 100. The semiconductor chip 200 may be adhered and fixed to the substrate 100 through the adhesive member 270 so as for an inactive surface NACT of the semiconductor chip 200 to face the substrate 100. A bonding pad 230 may be disposed at both edges of an active surface ACT of the semiconductor chip 200. The semiconductor chip 200 may be electrically connected to a substrate pad 140 through a wire 250.

Even in the semiconductor package 1000h according to the current embodiment, the stress buffer layer 400 may be disposed at both edge parts of the substrate 100. The stress buffer layer 400 may be disposed in the structure of FIG. 2A. However, the stress buffer layer 400 is not limited to the structure of FIG. 2A and may be of course disposed in various structures as in FIGS. 2B to 2E and 5B. Due to the presence of the stress buffer layer 400, in the semiconductor package 1000h according to the current embodiment, stress to be applied to the substrate 100 may be buffered, and the bending of the substrate 100 and the failure of the external connection member 600 may be prevented.

FIG. 13 is a cross-sectional view of a semiconductor package 2000c according to another embodiment of the inventive concept. For convenience of description, the above description will be concisely repeated or omitted.

Referring to FIG. 13, the semiconductor package 2000c according to the current embodiment may include four (first to fourth) semiconductor chips 200-1, 200-2, 200-3, and 200-4 stacked on the substrate 100. Each of the first to fourth semiconductor chips 200-1, 200-2, 200-3, and 200-4 may be adhered and fixed to the substrate 100 or an active surface ACT of a semiconductor chip disposed therebelow through the adhesive member 270 so as for an inactive surface NACT thereof to face the substrate 100.

The first to fourth semiconductor chips 200-1, 200-2, 200-3, and 200-4 may be stacked in a zigzag form as shown in FIG. 13. That is, the first to fourth semiconductor chips 200-1, 200-2, 200-3, and 200-4 may be stacked on the substrate 100 so that the first and third semiconductor chips 200-1 and 200-3 protrude to the left, and the second and fourth semiconductor chips 200-2 and 200-4 protrude to the right. Due to the zigzag stacking structure, a bonding pad of each of the first to fourth semiconductor chips 200-1, 200-2, 200-3, and 200-4 may be disposed only at any one exposed edge part. For example, a first bonding pad 230-1 of the first semiconductor chip 200-1 and a third bonding pad 230-3 of the third semiconductor chip 200-3 may be disposed at left edge parts, and a second bonding pad 230-2 of the second semiconductor chip 200-2 and a fourth bonding pad 230-4 of the fourth semiconductor chip 200-4 may be disposed at right edge parts.

The first to fourth semiconductor chips 200-1, 200-2, 200-3, and 200-4 may be electrically connected to substrate pads 140 through the first to fourth bonding pads 230-1, 230-2, 230-3, and 230-4 and wires 250-1, 250-2, 250-3, and 250-4, respectively. The first to fourth semiconductor chips 200-1, 200-2, 200-3, and 200-4 may input/output data by using a single channel or two channels. For example, when two channels are used, the first and third semiconductor chips 200-1 and 200-3 may use a first channel, and the second and fourth semiconductor chips 200-2 and 200-4 may use a second channel.

The first to fourth semiconductor chips 200-1, 200-2, 200-3, and 200-4 may be stacked in a stepped form instead of the zigzag form. Alternatively, the first to fourth semiconductor chips 200-1, 200-2, 200-3, and 200-4 may be stacked so as to protrude in four directions. When the first to fourth semiconductor chips 200-1, 200-2, 200-3, and 200-4 protrude in four directions, bonding pads may be disposed at respective protruding edge parts, and substrate pads may be disposed at four side edges on the substrate in correspondence with the bonding pads. When the first to fourth semiconductor chips 200-1, 200-2, 200-3, and 200-4 protrude in four directions, data may be input/output by using four channels.

In a structure of the semiconductor package 2000c according to the current embodiment, a structure including four semiconductor chips is illustrated, but the structure of the semiconductor package 2000c according to the current embodiment is not limited thereto. That is, the structure of the semiconductor package 2000c according to the current embodiment may include five or more semiconductor chips. For example, the structure of the semiconductor package 2000c according to the current embodiment may include eight semiconductor chips, and the eight semiconductor chips may be stacked so that four sets of two semiconductor chips protrude in four directions.

Even in the semiconductor package 2000c according to the current embodiment, the stress buffer layer 400 may be disposed at both edge parts of the substrate 100. The stress buffer layer 400 may be disposed in the structure of FIG. 2A. However, the stress buffer layer 400 is not limited to the structure of FIG. 2A and may be of course disposed in various structures as in FIGS. 2B to 2E and 5B. Due to the presence of the stress buffer layer 400, in the semiconductor package 2000c according to the current embodiment, stress to be applied to the substrate 100 may be buffered, and the bending of the substrate 100 and the failure of the external connection member 600 may be prevented.

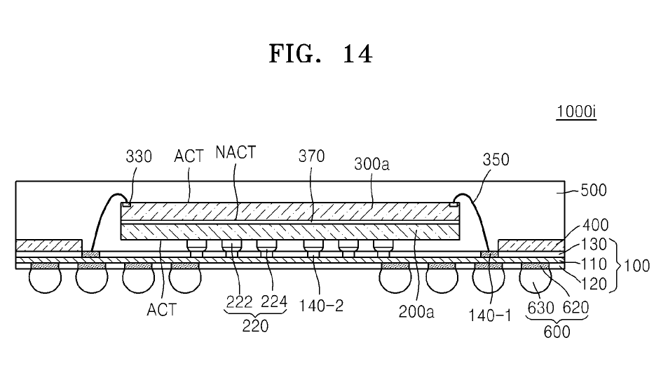

FIG. 14 is a cross-sectional view of a semiconductor package 1000i according to another embodiment of the inventive concept. For convenience of description, the above description will be concisely repeated or omitted.

Referring to FIG. 14, the semiconductor package 1000i according to the current embodiment may include two (first and second) semiconductor chips 200a and 300a stacked on the substrate 100. The first semiconductor chip 200a may be stacked on the substrate 100 by flip-chip bonding. That is, the first semiconductor chip 200a may be stacked so as for an active surface ACT thereof to face the substrate 100 and may be electrically connected to a second substrate pad 140-2 of the substrate 100 through a first bump 220.

The second semiconductor chip 300a may be adhered and fixed onto the first semiconductor chip 200a through an adhesive member 370, e.g., a DAF. In the second semiconductor chip 300a, an inactive surface NACT may face the first semiconductor chip 200a, and an active surface ACT may face upwards. A bonding pad 330 may be disposed at both edge parts of the second semiconductor chip 300a, and the second semiconductor chip 300a may be electrically connected to a first substrate pad 140 of the substrate through the bonding pad 330 and a wire 350.

In the semiconductor package 1000i according to the current embodiment, the stress buffer layer 400 may be disposed at both edge parts of the substrate 100. The stress buffer layer 400 may be disposed in various structures as in FIGS. 2A to 2E and 5B. Due to the presence of the stress buffer layer 400, in the semiconductor package 1000i according to the current embodiment, stress to be applied to the substrate 100 may also be buffered, and the bending of the substrate 100 and the failure of the external connection member 600 may be prevented. As shown in FIG. 14, a portion of the sealing member 500 may be formed between the lower-most semiconductor chip 200a and the package substrate 100.

FIG. 15 is a cross-sectional view of a semiconductor package 1000j according to another embodiment of the inventive concept. For convenience of description, the above description will be concisely repeated or omitted.

Referring to FIG. 15, the semiconductor package 1000j according to the current embodiment may include the substrate 100, a first semiconductor chip 200b, a second semiconductor chip 300, the stress buffer layer 400, the sealing member 500, and the external connection member 600.

The first semiconductor chip 200b may include a body part 211, a wiring part 212, a through substrate via (TSV, such as a through-silicon via) 207, a substrate connection member 150, and an upper protective layer 214. The first semiconductor chip 200b may be formed on the basis of an active wafer as described above. The body part 211 and the wiring part 212 are the same as described with reference to FIG. 1.

The substrate connection member 150 may include a first lower pad 152 and a first connection member 154. The first lower pad 152 may be formed on a lower surface of the wiring part 212 and of a conductive material and may be electrically connected to the TSV 207 through a multi-layer wiring of the wiring part 212. According to circumstances, the TSV 207 may be formed by passing through the wiring part 212, and in this case, the first lower pad 152 may be directly connected to the TSV 207.

The first lower pad 152 may be formed of Al, Cu, or the like and by a pulse plating or DC plating method. The first connection member 154 may be formed of a conductive material, e.g., Cu, Al, Ag, Sn, Au, solder, or the like. However, materials of the first lower pad 152 and the first connection member 154 are not limited to the materials described above.

The first connection member 154 may be formed in multiple layers or in a single layer. For example, when the first connection member 154 is formed in multiple layers, the first connection member 154 may include a Cu pillar and solder. When the first connection member 154 is formed in a single layer, the first connection member 154 may be formed of Sn—Ag solder or Cu.

The TSV 207 may be connected to the first lower pad 152 by passing through the body part 211. Although the TSV 207 is formed in a via-middle structure in the current embodiment, the TSV 207 is not limited thereto and may be of course formed in a via-first or via-last structure. As a reference, the TSV 207 may be classified into the via-first, via-middle, and via-last structures. The via-first structure indicates a structure in which the TSV 207 is formed before an integrated circuit layer is formed, the via-middle structure indicates a structure in which the TSV 207 is formed after the integrated circuit layer is formed and before the wiring part 212 is formed, and the via-last structure indicates a structure in which the TSV 207 is formed after the wiring part 212 is formed. In the current embodiment, the TSV 207 is formed in the via-middle structure in which the TSV 207 is formed after the wiring part 212 is formed, and based on the via-middle structure, the TSV 207 may be formed up to the wiring part 212 by passing through the body part 211.

The TSV 207 may include at least one metal. For example, the TSV 207 may include a barrier metal layer (not shown) and a wiring metal layer (not shown). The barrier metal layer may include at least one material selected from the group consisting of tungsten (W), tungsten nitride (WN), tungsten carbide (WC), titanium (Ti), titanium nitride (TiN), tantalum (Ta), tantalum nitride (TaN), ruthenium (Ru), cobalt (Co), manganese (Mn), nickel (Ni), and nickel boride (NiB) and may be formed in a single layer or multiple layers. The wiring metal layer may include Cu or W. For example, the wiring metal layer may be formed of Cu, a copper-tin alloy (CuSn), a copper-magnesium alloy (CuMg), a copper-nickel alloy (CuNi), a copper-zinc alloy (CuZn), a copper-palladium alloy (CuPd), a copper-gold alloy (CuAu), a copper-rhenium (CuRe), a copper-tungsten alloy (CuW), W, or a W alloy but is not limited thereto. For example, the wiring metal layer may include one or more materials selected from the group consisting of Al, Au, beryllium (Be), bismuth (Bi), Co, Cu, hafnium (Hf), indium (In), Mn, molybdenum (Mo), Ni, lead (Pb), Pd, platinum (Pt), rhodium (Rh), Re, ruthenium (Ru), Ta, tellurium (Te), Ti, W, Zn, and zirconium (Zr) and may include one or more stacking structures. However, materials of the TSV 207 are not limited to the materials described above. The barrier metal layer and the wiring metal layer may be formed by a physical vapor deposition (PVD) process or a chemical vapor deposition (CVD) process but are not limited thereto.

A spacer insulating layer (not shown) may be interposed between the TSV 207 and the body part 211. The spacer insulating layer may prevent the TSV 207 from directly contacting circuit devices inside the body part 211. The spacer insulating layer may be formed of an oxide film, a nitride film, a carbide film, a polymer, or a combination thereof. According to one or more embodiments of the inventive concept, a CVD process may be used to form the spacer insulating layer. The spacer insulating layer may be formed of a high aspect ratio process (HARP) oxide film based on ozone/tetra-ethyl ortho-silicate (O₃/TEOS) formed by a sub-atmospheric CVD process. The spacer insulating layer may not be formed on an upper surface of the TSV 207.

The upper protective layer 214 functions to protect the first semiconductor chip 200b. The upper protective layer 214 may be formed of an oxide film, a nitride film, or a dual layer of the oxide film and the nitride film. The upper protective layer 214 may be formed of an oxide film, e.g., a silicon oxide film (SiO₂), by using a high density plasma (HDP)-CVD process.

An upper pad 132 may be disposed on the upper protective layer 214. The upper pad 132 may be electrically connected to the TSV 207 passing through the upper protective layer 214. The upper pad 132 may be formed in a process of forming the TSV 207. Alternatively, the upper pad 132 may be formed in a structure in which the upper pad 132 is connected to the TSV 207 through a rewiring (not shown) instead of being directly formed on the TSV 207.

The second semiconductor chip 300 may include a body part 311, a wiring part 312, and a chip connection member 320. The body part 311 and the wiring part 312 are the same as described with respect to the body part 211 and the wiring part 212 of the first semiconductor chip 200b. Accordingly, a detailed description thereof is omitted. Unlike the first semiconductor chip 200b, no TSVs may be formed in the body part 311 of the second semiconductor chip 300. However, it is not definitely excluded that TSVs are included in the second semiconductor chip 300.

The chip connection member 320 may include a second lower pad 322 and a second connection member 324. The second lower pad 322 may be formed on a lower surface of the wiring part 312 and of a conductive material and may be electrically connected to an integrated circuit layer (not shown) inside the body part 311 through a multi-layer wiring of the wiring part 312. A material and a forming method of the second lower pad 322 are the same as described above with respect to the first lower pad 152 of the first semiconductor chip 200b. The second connection member 324 may be formed on the second lower pad 322. A material and a forming method of the second connection member 324 are also the same as described above with respect to the first connection member 154 of the first semiconductor chip 200b. However, the second connection member 324 may be formed with a smaller size and a smaller interval than those of the first connection member 154. Of course, the size and interval of the second connection member 324 may be substantially the same as those of the first connection member 154.

By coupling the second connection member 324 to the upper pad 132 of the first semiconductor chip 200b, integrated circuits inside the second semiconductor chip 300 may be electrically connected to the external connection member 600 of the substrate 100 through the TSV 207 of the first semiconductor chip 200b. As described above, since the second connection member 324 is coupled to the upper pad 132 of the first semiconductor chip 200b, an arrangement position of the second connection member 324 may be determined according to an arrangement position of the TSV 207 of the first semiconductor chip 200b. Of course, when the upper pad 132 is disposed at another part through the rewiring instead of being directly disposed on the TSV 207, the second connection member 324 may be disposed at a position other than a position of the TSV 207.

Both the first semiconductor chip 200b and the second semiconductor chip 300 may be memory devices or non-memory devices, or any one of the first semiconductor chip 200b and the second semiconductor chip 300 may be a memory device, and the other one may be a non-memory device. For example, the first semiconductor chip 200b may be a logic device, and the second semiconductor chip 300 may be a memory device. In addition, as shown in FIG. 15, a size of the first semiconductor chip 200b may be larger than that of the second semiconductor chip 300. The size difference may be caused by a structure in which the first semiconductor chip 200b is mounted on the substrate 100 having a relatively large size. For example, with the first semiconductor chip 200b having a large size, by disposing the substrate connection member 150 with a large size and a large interval, a process of mounting the first semiconductor chip 200b on the substrate 100 may be easily performed. Of course, it is not excluded that the first semiconductor chip 200b is formed to have a size that is substantially the same as that of the second semiconductor chip 300.

Separately from the sealing member 500, a gap-fill part (not shown) may be filled between the first semiconductor chip 200b and the second semiconductor chip 300. Of course, without the separate gap-fill part, the sealing member 500 may be filled between the first semiconductor chip 200b and the second semiconductor chip 300. The gap-fill part may be formed of a non-conductive adhesive or a non-conductive tape exhibiting a fluxing effect. The wording “exhibiting a fluxing effect” may indicate a phenomenon that as in common resin-group flux, a coating film formed so as to block the air by coating a metallic surface of a soldered body reduces an oxide metal on the metallic surface in soldering due to an active component of the coating film and is simultaneously pushed out by melted solder, and accordingly, the melted solder contacts the metallic surface, and a residual coating film functions as an insulating material between the metallic surface and a circuit device.

Besides, the substrate 100, the stress buffer layer 400, the sealing member 500, the external connection member 600, and the like are the same as described with respect to the semiconductor package 1000 of FIG. 1. Therefore, a detailed description thereof is omitted. Even in the semiconductor package 1000j according to the current embodiment, to decrease a height of the semiconductor package 1000j, the sealing member 500 may be formed so as to expose the upper surface of the second semiconductor chip 300. Nonetheless, as can be seen in FIG. 15, in certain embodiments, a bottom surface of a lowermost chip (e.g., 200b) may be higher than a top surface of the stress buffer layer 400.

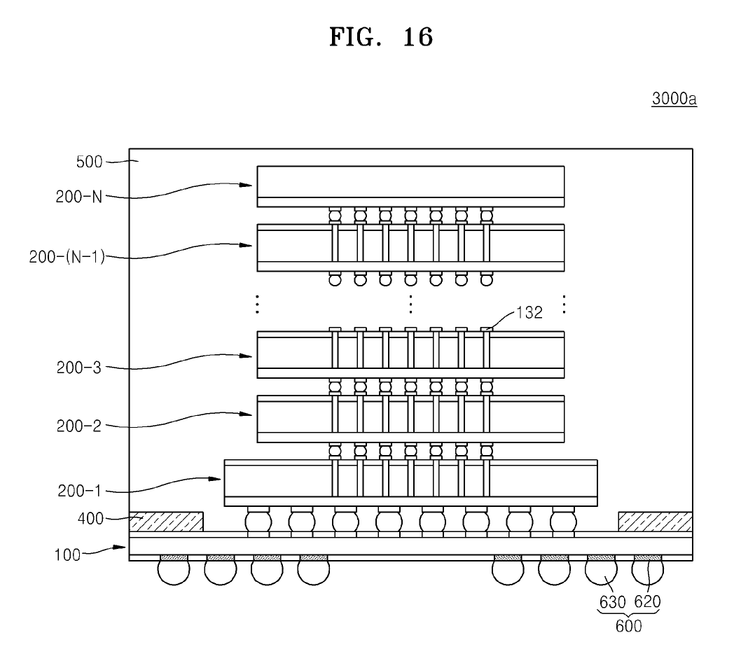

FIG. 16 is a cross-sectional view of a semiconductor package 3000a according to another embodiment of the inventive concept. For convenience of description, the above description will be concisely repeated or omitted.

Referring to FIG. 16, the semiconductor package 3000a according to the current embodiment may include three or more semiconductor chips on the substrate 100. For example, the semiconductor package 3000a may include a first semiconductor chip 200-1, a second semiconductor chip 200-2, . . . , an (N−1)th semiconductor chip 200-(N−1), and an Nth semiconductor chip 200-N. Herein, N may be an integer that is 3 or greater.

Each of the first semiconductor chip 200-1, the second semiconductor chip 200-2, . . . , and the (N−1)th semiconductor chip 200-(N−1) may include a TSV. However, the Nth semiconductor chip 200-N as the uppermost semiconductor chip may not include a TSV.

Although FIG. 16 shows that only upper pads 132 exist on the upper surface of the third semiconductor chip 200-3, some semiconductor chips are omitted in FIG. 16 for convenience of drawing, and actually, the upper pads 132 of the third semiconductor chip 200-3 and chip connection members of a semiconductor chip on the third semiconductor chip 200-3 may be connected to each other. In addition, the same concept may be applied to a lower surface part of the (N−1)th semiconductor chip 200-(N−1).

Even in the semiconductor package 3000a according to the current embodiment, to decrease a height of the semiconductor package 3000a, the sealing member 500 may be formed so as to expose the upper surface of the uppermost semiconductor chip, i.e., the Nth semiconductor chip 200-N. The semiconductor package 3000a according to the current embodiment may be almost the same as the semiconductor package 1000j of FIG. 15 except for the fact that the semiconductor package 3000a includes three or more semiconductor chips. Therefore, a more detailed description thereof is omitted.

FIGS. 17A and 17B are a cross-sectional view and a top view of a semiconductor package 1000k according to another embodiment of the inventive concept. FIG. 17A may correspond to a part cut along line II-II′ of FIG. 17B. For convenience of description, the above description will be concisely repeated or omitted.

Referring to FIGS. 17A and 17B, the semiconductor package 1000k according to the current embodiment may be almost similar to the semiconductor package 1000 of FIG. 1 except for a substrate 100a and a sealing member 500b. In one embodiment, a window W may be formed at a center part of the substrate 100a. The window W may be, for example, a through hole formed in a long drain form at the center part of the substrate 100a in order to smooth a flow of the sealing member 500b of a liquid state in a molding process of sealing semiconductor chips 200 and 300 with the sealing member 500b. The window W may be in the form of a trench, for example. In general, since an EMC is frequently used as the sealing member 500b, the window W may be called an EMC window.

In the molding process, a sealing member protrusion part 520 may be formed as shown in FIG. 17A by flowing the sealing member 500b of a liquid state through the window W and hardening the sealing member 500b. The sealing member protrusion part 520 may be formed in a structure, such as a head of a rivet, thereby functioning to firmly assemble the substrate 100a with the sealing member 500b and the semiconductor chips 200 and 300.

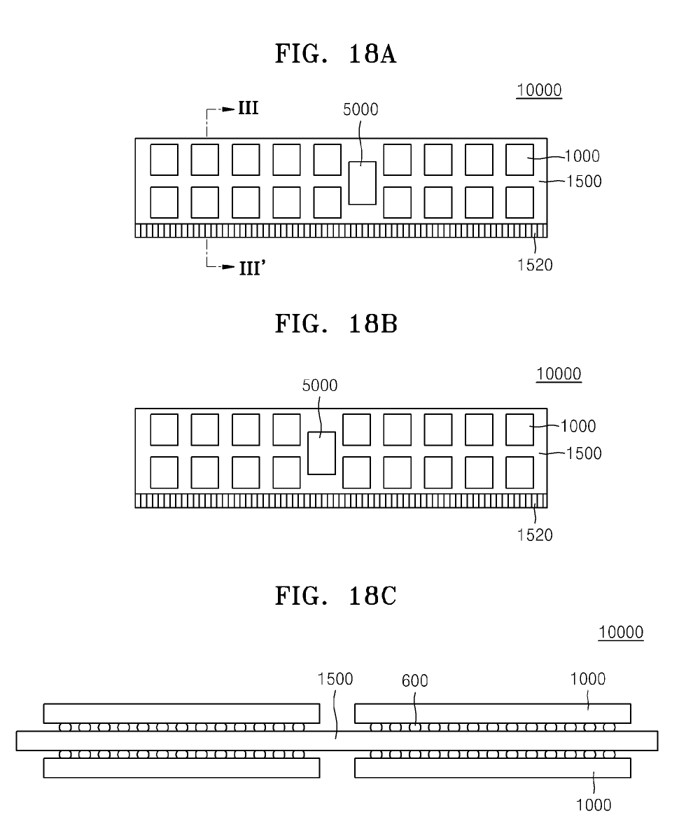

FIGS. 18A and 18B are a top view and a bottom view of a memory module 10000, and FIG. 18C is a cross-sectional view along line III-III′ of FIG. 18A.

Referring to FIGS. 18A to 18C, the memory module 10000 may form an electronic device including a module substrate 1500, the semiconductor package 1000, and a buffer chip 5000. For the purposes of this disclosure, an electronic device may refer generally to a semiconductor chip, a semiconductor package, a semiconductor module, a memory card, a cellular phone, a computer, or other apparatuses or products described, for example, in connection with the various figures included in this disclosure. A semiconductor device, as used herein, refers to a semiconductor chip, semiconductor package, or package-on-package device.

The module substrate 1500 may be similar to the substrate 100 in the semiconductor package 1000 of FIG. 1. However, the module substrate 1500 may be thicker and have a greater number of wiring layers than the substrate 100. For example, the module substrate 1500 may be implemented by forming a Cu foil on a plate, which is obtained by compressing a phenol or epoxy glass (or FR-4) resin or the like to a predetermined thickness, and patterning the Cu foil to form a circuit wiring. In addition, the Cu foil may be formed in three or more layers by using an insulator named prepreg, and the module substrate 1500 may include three or more wiring layers according to the number of layers of the Cu foil.

The module substrate 1500 may be classified into a single layer PCB having wirings formed on only one surface thereof and a double layer PCB having wirings formed on both surfaces thereof. In the memory module 10000 according to the current embodiment, the module substrate 1500 may be a double layer PCB. A plurality of semiconductor packages 1000 and the buffer chip 5000 may be mounted on both surfaces of the module substrate 1500 through a connection member, such as a solder ball, as shown in FIGS. 18A to 18C. For example, for a server-oriented memory module, 36 semiconductor packages 1000 may be mounted on one module substrate 1500.

The semiconductor package 1000 may be the semiconductor package 1000 of FIG. 1. However, the semiconductor package 1000 is not limited thereto, and the various semiconductor packages illustrated in FIGS. 1 to 17B may be of course mounted on the module substrate 1500. As shown in FIG. 18C, the semiconductor package 1000 may be mounted on the module substrate 1500 through the external connection member 600.

As described above, an existing semiconductor package has a problem that because of stress applied to the substrate 100 due to a CTE difference between the substrate 100 and the sealing member 500, the substrate 100 is bent, and accordingly, the failure, such as a bad contact, a crack, a separation, or the like, of the external connection member 600 occurs, thereby weakening TC reliability in BLR. However, in the semiconductor package 1000 according to the current embodiment, the stress buffer layer 400 is disposed at edge parts of the substrate 100, and due to the presence of the stress buffer layer 400, the bending of the substrate 100 and the failure of the external connection member 600 may be prevented. Accordingly, the semiconductor packages 1000 may be firmly fixed and maintained onto the module substrate 1500, thereby contributing to the improvement of TC reliability in BLR.

The buffer chip 5000 functions to relay data transmission by being disposed between DRAMs and a memory controller (not shown). For example, the buffer chip 5000 may be an advanced memory buffer (AMB), and the AMB may be connected to all DRAMs to store data delivered from the memory controller in a DRAM and read requested data from a DRAM and transmit the read data to the memory controller and may relay a data storing command and a data request command of the memory controller to an AMB of a memory module inserted in a next slot. With the buffer chip 5000, the memory module 10000 having a high transmission bandwidth and a high capacity may be implemented. According to circumstances, the buffer chip 5000 may be omitted from the memory module 10000 according to the current embodiment.

In FIGS. 18A and 18B, reference numeral 1520 indicates terminal pins of the module substrate 1500, and when the terminal pins 1520 are formed on only one surface of the module substrate 1500, the memory module 10000 is a single in-line memory module (SIMM), and when the terminal pins 1520 are formed on both surfaces of the module substrate 1500, the memory module 10000 is a dual in-line memory module (DIMM). The module substrate 1500 may be inserted into a socket of a main board in a laptop computer, a smart phone, a server computer, or the like, and an electrical contact between the module substrate 1500 and the main board may be achieved through the terminal pins 1520.

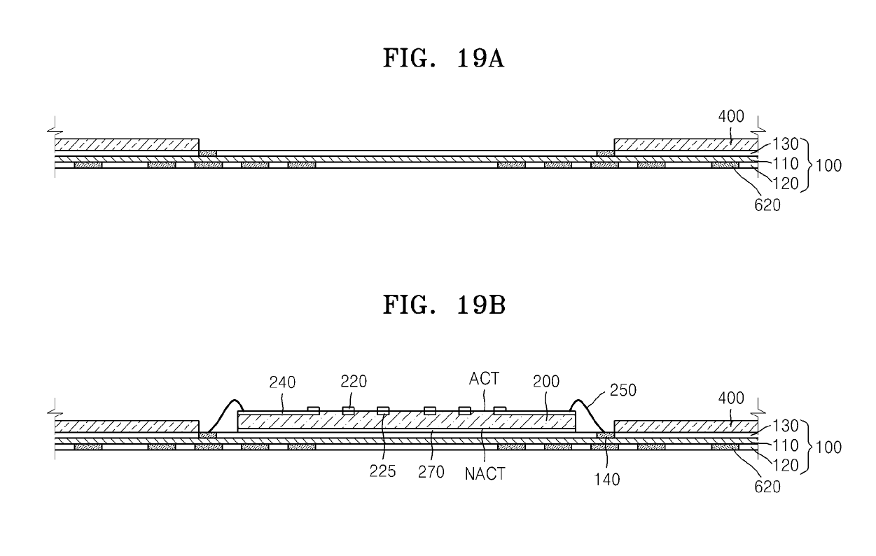

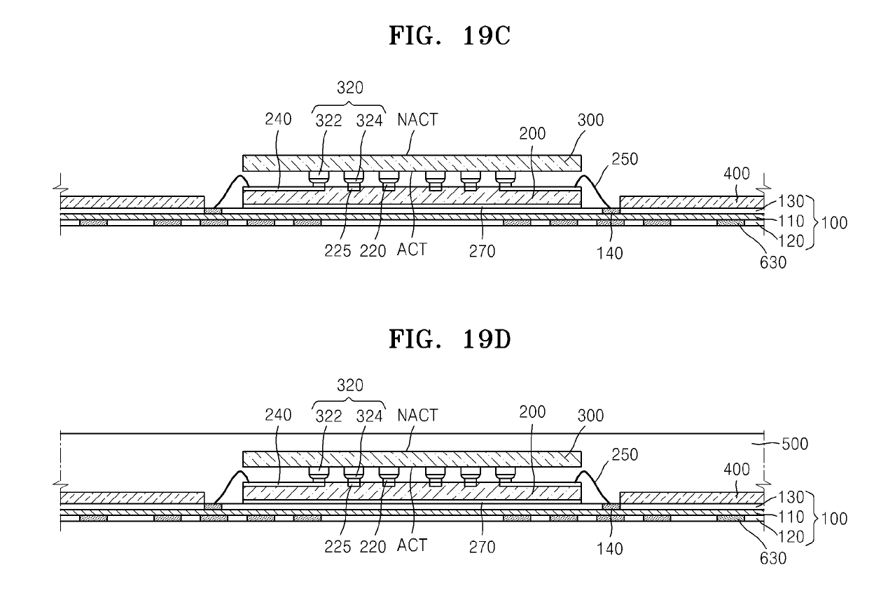

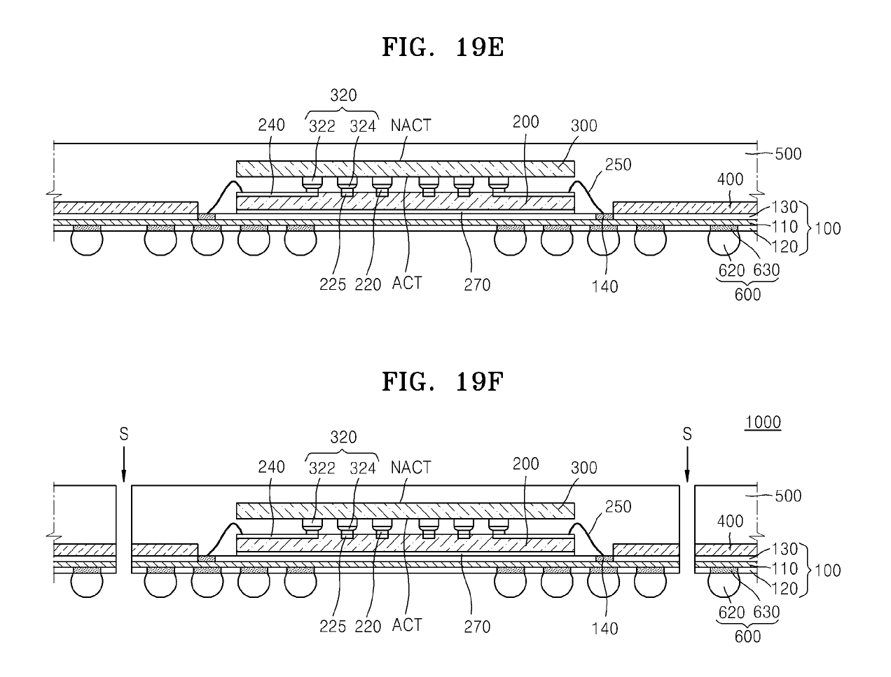

FIGS. 19A to 19F are cross-sectional views for describing a method of manufacturing a semiconductor package, according to an embodiment of the inventive concept.

Referring to FIG. 19A, the stress buffer layer 400 is formed on the substrate 100.

The substrate 100 may include the body layer 110, the lower protective layer 120, and the upper protective layer 130. The substrate pad 140 may be disposed on the upper surface of the substrate 100, and the external lower pad 620 may be disposed on the lower surface of the substrate 100. The substrate 100 may be, for example, a strip substrate in a long rectangular form on which a plurality of first semiconductor chips 200 may be horizontally stacked, as an MUF PCB.

The stress buffer layer 400 may have a relatively lower modulus compared to the other components of the semiconductor package. For example, in one embodiment, the stress buffer layer 400 may have a low modulus of about 0.1 MPa to about 500 MPa and have a high CTE of about 100 ppm to about 1000 ppm. The stress buffer layer 400 may be formed, for example, by coating a liquid-phase material on the substrate 100 by a printing or depositing method, or by adhering a film-type thin layer onto the substrate 100 through film lamination or the like. The printing method may include various printing methods, such as printing using stamp, laser printing, screen printing, stencil printing, inkjet printing, roll printing, and the like.

The stress buffer layer 400 may be variously formed in a desired form on the substrate 100. For example, the stress buffer layer 400 may be formed on the substrate 100 in various forms as illustrated in FIGS. 2A to 2E and 5B.

Referring to FIG. 19B, the first semiconductor chip 200 is mounted on the substrate 100. For example, the first semiconductor chip 200 may be mounted on the substrate 100 by adhering and fixing the first semiconductor chip 200 to the substrate 100 through the adhesive member 270 so that the inactive surface NACT of the first semiconductor chip 200 faces the substrate 100, and electrically connecting the bonding pads (not shown) of the first semiconductor chip 200 to the substrate pads 140 of the substrate 100 through the wire 250.

As a reference, to form a mirror-type stacking structure, pads, rewirings, and bumps as illustrated in FIG. 7A may be disposed on the active surface ACT of the first semiconductor chip 200. FIG. 19B shows only the bump pads 225, the rewirings 240, and the first bumps 220 for convenience of drawing.

Referring to FIG. 19C, the second semiconductor chip 300 is mounted on the first semiconductor chip 200, for example, by a flip-chip method. For example, the second semiconductor chip 300 may be stacked on the first semiconductor chip 200 so that the second bumps 320 of the second semiconductor chip 300 are physically and electrically coupled to the first bumps 220 of the first semiconductor chip 200. To form the mirror-type stacking structure, pads, rewirings, and bumps as illustrated in FIG. 7B may be disposed on the active surface ACT of the second semiconductor chip 300. FIG. 19C shows only the second bumps 320 for convenience of drawing.

Referring to FIG. 19D, the first semiconductor chip 200 and the second semiconductor chip 300 are sealed by the sealing member 500. The sealing member 500 may be formed by an MUF process or an e-MUF process. When the sealing member 500 is formed by the e-MUF process, the upper surface, i.e., the inactive surface NACT, of the second semiconductor chip 300 may be exposed from the sealing member 500. As shown in FIG. 19D, the sealing member 500 may further seal the stress buffer layer 400.

Referring to FIG. 19E, the external connection member 600 is completed by disposing the connection member 630, e.g., a solder ball, on the external lower pad 620 on the lower surface of the substrate 100. The external connection member 600 may be connection terminals for mounting the semiconductor package on a module substrate.

Referring to FIG. 19F, semiconductor packages 1000 each including the stacking structure are individualized by a singulation process, such as sawing, in an arrow direction S. As shown in FIG. 19F, a side surface of the stress buffer layer 400 may be exposed from a side surface of the sealing member 500 in each of the semiconductor packages 1000. However, by not forming the stress buffer layer 400 at a portion to be sawed, the side surface of the stress buffer layer 400 may not be exposed from the sealing member 500 as illustrated in FIG. 4.

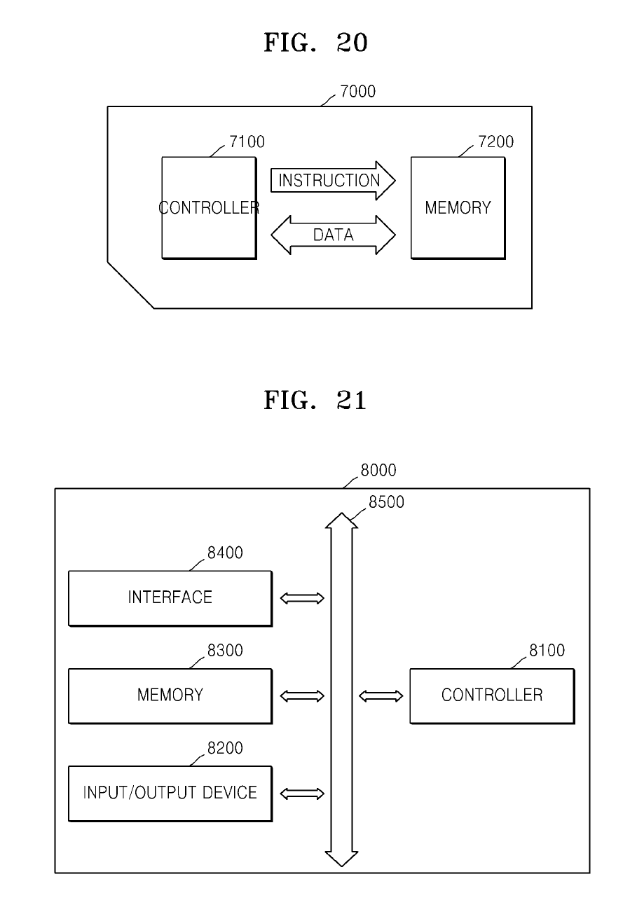

FIG. 20 is a block diagram of a memory card 7000 including a semiconductor package according to one or more embodiments of the inventive concept.

Referring to FIG. 20, in the memory card 7000, a controller 7100 and a memory 7200 may be arranged so as to exchange electrical signals. For example, when the controller 7100 sends an instruction, the memory 7200 may send data. The controller 7100 and/or the memory 7200 may include a semiconductor package according to any one of the embodiments of the inventive concept described above. The memory 7200 may include a memory array (not shown) or a memory array bank (not shown).

The memory card 7000 may be used for memory apparatuses such as various types of cards, e.g., a memory stick card, a smart media (SM) card, a secure digital (SD) card, a mini SD card, and a multi-media card (MMC).

FIG. 21 is a block diagram of an electronic system 8000 including a semiconductor package according to one or more embodiments of the inventive concept.

Referring to FIG. 21, the electronic system 8000 may include a controller 8100, an input/output device 8200, a memory 8300, and an interface 8400. The electronic system 8000 may be a mobile system or a system for transmitting or receiving information. The mobile system may be, for example, a personal digital assistant (PDA), a portable computer, a web tablet, a wireless phone, a mobile phone, a digital music player, or a memory card.

The controller 8100 may function to execute a program and to control the electronic system 8000. The controller 8100 may be, for example, a microprocessor, a digital signal processor, a microcontroller, or a similar device. The input/output device 8200 may be used to input or output data into or from the electronic system 8000.

The electronic system 8000 may exchange data with an external device, e.g., a personal computer (PC) or a network, by connecting to the external device using the input/output device 8200. The input/output device 8200 may be, for example, a keypad, a keyboard, or a display. The memory 8300 may store codes and/or data for an operation of the controller 8100 and/or store data processed by the controller 8100. The controller 8100 and the memory 8300 may include the semiconductor package according to any one of the embodiments of the inventive concept. The interface 8400 may be a data transmission path between the electronic system 8000 and an external device. The controller 8100, the input/output device 8200, the memory 8300, and the interface 8400 may communicate with each other via a bus 8500.

For example, the electronic system 8000 may be used for mobile phones, MP3 players, navigation machines, portable multimedia players (PMPs), solid state disks (SSDs), and household appliances.

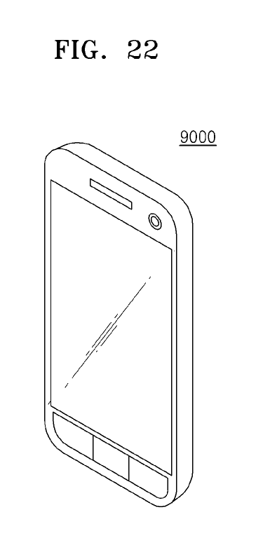

FIG. 22 is a perspective view of an electronic device to which a semiconductor package according to one or more embodiments of the inventive concept may be applied.

FIG. 22 is an example in which the electronic system 8000 of FIG. 14 is applied to a mobile phone 9000. Alternatively, the electronic system 8000 may be applied to electronic devices, such as portable laptop computers, MP3 players, navigation machines, SSDs, vehicles, and household appliances.

While various aspects of the inventive concept have been particularly shown and described with reference to exemplary embodiments thereof, it will be understood that various changes in form and details may be made therein without departing from the spirit and scope of the following claims.

What is claimed is:

1. A semiconductor package comprising:
a substrate;
a first semiconductor chip disposed on a first surface of the substrate, the first semiconductor chip either the only semiconductor chip disposed on the first surface of the substrate or a bottom-most semiconductor chip formed on the first surface of the substrate;
a plurality of external connection terminals disposed on a second surface of the substrate that is opposite to the first surface of the substrate;
a stress buffer layer formed on the first surface of the substrate to vertically overlap at least one of the plurality of external connection members, wherein the stress buffer layer is formed on an edge part of the substrate and does not contact or vertically overlap the first semiconductor chip; and
a sealing member covering the first chip and the stress buffer layer.

2. The semiconductor package of claim 1, wherein the stress buffer layer has a modulus that reduces stress and/or strain according to a difference in a coefficient of thermal expansion (CTE) between the substrate and the sealing member.

3. The semiconductor package of claim 1, wherein the stress buffer layer has a modulus that is lower than that of the substrate.

4. The semiconductor package of claim 1, wherein the stress buffer layer has a modulus that is lower than that of each of the substrate, the first semiconductor chip, and the sealing member.

5. The semiconductor package of claim 1, wherein the stress buffer layer is formed at a portion on the first surface of the substrate outside of a portion where the first semiconductor chip is disposed.

6. The semiconductor package of claim 1, wherein the stress buffer layer includes at least two buffer structures at opposite ends of the substrate, each buffer structure extending lengthwise along an edge part of the substrate and extending width-wise from inside an edge of the substrate to the edge of the substrate.

7. The semiconductor package of claim 1, wherein the stress buffer layer is formed on the first surface of the substrate in a symmetrical form based on the first semiconductor chip.

8. The semiconductor package of claim 1, wherein the stress buffer layer is formed on the first surface of the substrate and at two facing sides or four sides of the first semiconductor chip.

9. The semiconductor package of claim 1, wherein the stress buffer layer is exposed from a side surface of the sealing member.

10. The semiconductor package of claim 1, further comprising a second semiconductor chip stacked on the first semiconductor chip, wherein:
the first semiconductor chip is disposed on the substrate and inactive surface thereof faces the first surface of the substrate, and the first semiconductor chip is electrically connected to the substrate through a plurality of wires, and
the second semiconductor chip is stacked on the first semiconductor chip through a bump and an active surface thereof faces an active surface of the first semiconductor chip, and the second semiconductor chip electrically connects to the substrate through the bump, a rewiring of the first semiconductor chip, and the wire.

11. The semiconductor package of claim 1, wherein the first semiconductor chip is part of a stack of semiconductor chips including at least a second semiconductor chip stacked on the first semiconductor chip, and
wherein a semiconductor chip of the stack of semiconductor chips closest to the substrate is connected to the substrate through a plurality of bumps, and remaining semiconductor chips of the stack of semiconductor chips are electrically connected to the substrate through a plurality of through substrate vias.

12. An electronic device, comprising:
a package substrate;
a first semiconductor chip disposed on a first surface of the package substrate, the first semiconductor chip either the only semiconductor chip disposed on the first surface of the package substrate or a bottom-most semiconductor chip formed on the first surface of the package substrate;
a plurality of external connection terminals disposed on a second surface of the package substrate that is opposite to the first surface of the package substrate;
a capping layer covering the first semiconductor chip and covering the first surface of the substrate;
a first buffer structure formed between the first surface of the substrate and the capping layer at a first edge portion of the substrate, the first buffer structure separated from a first side of the first semiconductor chip by a predetermined distance; and
a second buffer structure formed between the first surface of the substrate and the capping member at a second edge portion of the substrate, the second edge portion opposite the first edge portion, and the second buffer structure separated from a second side of the first semiconductor chip by a predetermined distance,
wherein each of the first and second buffer structures have a modulus that is less than the modulus of the package substrate and less than the modulus of the capping layer.

13. The electronic device of claim 12, wherein each of the first and second buffer structures covers a respective set of external connection terminals of the plurality of connection terminals.

14. The electronic device of claim 12, wherein the first and second buffer structures are part of a stress buffer layer, and the stress buffer layer has a modulus that reduces a stress or strain influence from the capping layer when the package substrate contracts or expands.

15. The electronic device of claim 12, wherein the modulus of each of the first and second buffer structures is less than 5% of the modulus of each of the package substrate and the capping layer.

16. The electronic device of claim 12, further comprising:
a module substrate on which the package substrate is mounted.

17. A semiconductor device, comprising:
a substrate;
a plurality of external connection terminals on a bottom surface of the substrate;
a stack of semiconductor chips disposed on a top surface of the substrate, the stack of semiconductor chips including a lower-most semiconductor chip, and one or more additional semiconductor chips;
a capping layer disposed on the top surface of the substrate; and
an edge interface layer formed at an interface between the capping layer and the top surface of the substrate, at a location outside of outer boundaries of the lower-most semiconductor chip and separated from the lower-most semiconductor chip,
wherein the edge interface layer is formed of a material that reduces a stress or strain influence from the capping layer on the substrate when the substrate contracts or expands.

18. The semiconductor package of claim 17, wherein the edge interface layer has a modulus that is lower than that of each of the substrate, the semiconductor chips, and the capping layer, and
the edge interface layer is formed at an edge portion on the first surface of the substrate and covers at least a plurality of outer-most external connection terminals of the plurality of external connection terminals.

19. The semiconductor package of claim 18, wherein the substrate is a package substrate, and the edge interface layer extends to at least one edge of the package substrate, such that side surfaces of the package substrate and the edge interface layer are substantially coplanar.

20. The semiconductor package of claim 17, wherein the edge interface layer is formed at two opposite sides of the substrate, or at four sides of the substrate.
